(19) United States
(12) Patent Application Publication
(10) Pub. No.: US 2026/0096009 A1
(43) Pub. Date: Apr. 2, 2026

(54) SYSTEMS AND METHODS FOR COOLING DATACENTER COMPONENTS

(71) Applicant: MELLANOX TECHNOLOGIES, LTD., Yokneam (IL)

(72) Inventors: Yuval Dagan, Gilon (IL); Rom Becker, Ramat Yishai (IL); Shay Zaretsky, Kiryat Motzkin (IL); Yuval Blayer, Avtalyon (IL); Itamar Bartal, Yokneam Illit (IL); Roy Kauffman, Gilon (IL); Jacov Hanuka, Haifa (IL); Nir Einati, Raanana (IL)

(21) Appl. No.: 19/072,771

(22) Filed: Mar. 6, 2025

Related U.S. Application Data
(60) Provisional application No. 63/701,792, filed on Oct. 1, 2024.

(51) Int. Cl. H05K 1/02

(52) U.S. Cl. CPC H05K 1/0201; H05K 2201/064

(57) ABSTRACT

A system is disclosed to support the efficient cooling of components in a datacenter. An example of a system may include a Printed Circuit Board (PCB), one or more cages mounted on a surface of the PCB, and a heat exchange surface integrated into the PCB. The heat exchange surface may be configured to carry a heat transfer fluid that cools the one or more cages.

### CROSS-REFERENCE TO RELATED APPLICATION

The present application claims the benefit of and priority, under 35 U.S. C. § 119, to U.S. Provisional Application Ser. No. 63/701,792, filed Oct. 1, 2024, entitled “Embedded Cold Plate In PCB,” the entire disclosure of which is hereby incorporated herein by reference, in its entirety, for all that it teaches and for all purposes.

### FIELD OF THE DISCLOSURE

Embodiments of the present disclosure relate generally to thermal solutions for computing hardware, and more specifically to cooling components of a datacenter.

### BACKGROUND

Datacenter switch systems and associated modules may include connections between other switch systems, servers, racks, and devices. Such connections may be made using cables, transceivers, cage receptacles, and connector assemblies, which may include a shell or housing configured to protect these connections from damage.

As datacenters continue to operate at higher speeds (e.g., 100 Gb and beyond), the thermal demands on the components in the datacenters increase as well. Heat generation in datacenters occurs primarily due to the electricity used by servers, storage devices, and other hardware components, where nearly all the consumed energy is converted into heat as a byproduct of processing data, essentially meaning that for every watt of electricity used, a watt of heat is produced. The heat requires active and continuous management; otherwise, components of the datacenter may fail under extreme thermal loads. For instance, cage receptacles can generate heat during operation, which can result in the failure of system components connected thereto.

### GENERAL DESCRIPTION

Embodiments of the present disclosure aim to address at least some issues associated with thermal loads in a datacenter. Specifically, and without limitation, embodiments of the present disclosure provide systems and methods for cooling printed circuit boards (PCBs).

In some embodiments, a heat exchange surface is provided that can be integrated into a PCB. The term “integrated” refers hereinafter to implanted, embedded, and/or inset. The term “heat exchange surface” refers hereinafter to a cold plate, a cooling plate, a cooling coin, and/or any other device with at least one substantially planar surface configured to facilitate heat transfer. Embodiments of the present disclosure may be configured to be incorporated in a liquid-cooled switch and may further provide cooling capabilities to one or more cages that receive a connector plug. Examples of such connector plugs include, without limitation, an Octal Small Form-factor Pluggable (OSFP) or Quad Small Form-factor Pluggable (QSFP) cable connector.

The cold plate or cooling coin may receive fluid, such as water, from one or more fluid sources and may have one or more conduits to carry fluid across a bottom surface of the one or more cages. The cold plate or cooling coin may be machined to have a final height that matches or aligns with a height of the PCB. The one or more cages may connect with the PCB via a press fit feature. Alternatively or additionally, the one or more cages may be integrally formed as part of the PCB or may connect with the PCB in any other suitable manner. It may also be possible to provide a cold plate as described herein to conduct liquid inside a PCB to support cooling of other components of the PCB.

In some embodiments, apparatuses and associated methods of manufacturing are described that provide a cage receptacle assembly configured to receive a cable connector. The cage receptacle assembly may include a PCB with a cold plate or cooling coin incorporated therein.

The present disclosure relates in general to optical, active, and high-powered cables and associated connector assemblies used in conjunction with datacenter switch systems, modules, and other optical and electrical components. In particular, cages, shells, and housings of connector and receptacle assemblies are described which utilize heat dissipation units and elements that are configured to increase the thermal performance of connector assemblies.

Datacenter switch systems and associated modules may generally include connections between other switch systems, servers, racks, and devices. Such connections may be made using cables, transceivers, cage receptacles, and connector assemblies, which may include a shell or housing configured to protect these connections from damage. Often, these cage receptacles can generate heat during operation, which can result in the failure of system components.

Example aspects of the present disclosure include solutions to help cool one or more components of a datacenter as described herein.

In some embodiments, a system is provided that includes: a Printed Circuit Board (PCB); one or more cages mounted on a surface of the PCB; and a heat exchange surface integrated into the PCB and configured to carry a heat transfer fluid that cools the one or more cages.

According to some aspects, the heat exchange surface includes: an intake port; a discharge port; and a conduit, the intake port in fluid communication with the discharge port via the conduit.

According to some aspects, the heat exchange surface further includes: a base; and a cover plate secured to the base, were each of the base and the cover plate define a surface of the conduit.

According to some aspects, the conduit includes a plurality of channels machined into the base.

According to some aspects, the cover plate includes: a first end; a second end opposite the first end; the intake port proximate the first end; and the discharge port proximate the second end.

According to some aspects, the system further includes: a manifold secured to the heat exchange surface and in fluid communication with the intake port, the manifold detachably connectable to a heat transfer fluid source.

According to some aspects, the heat exchange surface is secured to the PCB via a press fit.

According to some aspects, the heat exchange surface is machined to have a final height that matches a height of the PCB.

According to some aspects, the PCB includes an upper PCB surface and a lower PCB surface, the heat exchange surface comprises a top surface and a bottom surface, the upper PCB surface is substantially level with the top surface, and the lower PCB surface is substantially level with the bottom surface.

According to some aspects, the one or more cages include: a first plurality of cages mounted to the upper PCB surface with a belly side of the first plurality of cages facing the upper PCB surface; and a second plurality of cages mounted to the lower PCB surface with a belly side of the second plurality of cages facing the lower PCB surface.

According to some aspects, each of the one or more cages is configured to receive a connector plug.

According to some aspects, the connector plug is a Quad Small Form-factor Pluggable (QSFP) plug or an Octal Small Form-factor Pluggable (OSFP) plug.

According to some aspects, a liquid-cooled switch is provided that includes the system or components thereof.

According to some aspects, a liquid-cooled server is provided that includes the system or components thereof.

In some embodiments, a liquid-cooled system is provided that includes: a Printed Circuit Board (PCB) including: an upper surface defining a first plane; and a lower surface defining a second plane. The liquid-cooled system may further include one or more cages mounted on each of the upper surface and the lower surface of the PCB; and a cooling coin embedded in the PCB, the cooling coin defining a pathway positioned in between the first plane and the second plane, the pathway configured to hold a heat transfer fluid.

According to some aspects, the cooling coin includes: an intake port in fluid communication with the pathway; and a discharge port in fluid communication with the pathway.

According to some aspects, the pathway includes a plurality of channels.

According to some aspects, the cooling coin includes a base and a cover plate.

In some embodiments, a system is provided that includes: a cooling plate, including: a first piece defining a fluid conduit; a second piece mountable to the first piece and configured to enclose the fluid conduit; and a plurality of ports positioned to enable fluid flow into and out of the fluid conduit.

According to some aspects, at least one of the plurality of ports is positioned in the second piece.

According to some aspects, the fluid conduit includes a plurality of fluid paths for channeling fluid from a first one of the plurality of ports to a second one of the plurality of ports.

According to some aspects, the cooling plate further includes: an inlet manifold mounted to the first piece and configured to channel fluid through a first one of the plurality of ports; and an outlet manifold mounted to the first piece and positioned to receive fluid exiting the fluid conduit through a second one of the plurality of ports.

According to some aspects, the system further includes: a first plurality of cages mounted adjacent the first piece; and a second plurality of cages mounted adjacent the second piece, where the first plurality of cages is in a belly-to-belly configuration relative to the second plurality of cages.

Any aspect in combination with any one or more other aspects.

Any one or more of the features disclosed herein.

Any one or more of the features as substantially disclosed herein.

Any one or more of the features as substantially disclosed herein in combination with any one or more other features as substantially disclosed herein.

Any one of the aspects/features/implementations in combination with any one or more other aspects/features/implementations.

Use of any one or more of the aspects or features as disclosed herein.

It is to be appreciated that any feature described herein can be claimed in combination with any other feature(s) as described herein, regardless of whether the features come from the same described implementation.

The details of one or more aspects of the disclosure are set forth in the accompanying drawings and the description below. Other features, objects, and advantages of the techniques described in this disclosure will be apparent from the description and drawings, and from the claims.

Numerous additional features and advantages of the present disclosure will become apparent to those skilled in the art upon consideration of the implementation descriptions provided hereinbelow.

Additional features and advantages are described herein and will be apparent from the following Description and the figures.

### BRIEF DESCRIPTION OF THE SEVERAL VIEWS OF THE DRAWINGS

Having thus described the disclosure in general terms, reference will now be made to the accompanying drawings, which are not necessarily drawn to scale:

FIG. 1 is a block diagram illustrating a computer system according to at least some embodiments of the present disclosure;

FIG. 2A is a block diagram illustrating an example network architecture according to at least some embodiments of the present disclosure;

FIG. 2B schematically illustrates various components of a network architecture according to at least some embodiments of the present disclosure;

FIG. 2C is a block diagram illustrating details of network devices according to at least some embodiments of the present disclosure;

FIG. 3 is a block diagram illustrating further details of a datacenter and components thereof according to at least some embodiments of the present disclosure;

FIG. 4 is a perspective view of a datacenter rack according to at least some embodiments of the present disclosure;

FIG. 5 is a block diagram illustrating fluid flow through at least some embodiments of the present disclosure;

FIG. 6 is a perspective view of a cage receptacle assembly according to at least some embodiments of the present disclosure;

FIGS. 7A-7B illustrate an example cable connector according to at least some embodiments of the present disclosure;

FIG. 8 is a perspective view of a system according to at least some embodiments of the present disclosure;

FIG. 9 is an exploded perspective view of certain components of the system of FIG. 8, according to at least some embodiments of the present disclosure;

FIG. 10 is a perspective view of certain components of the system of FIG. 8, according to at least some embodiments of the present disclosure;

FIG. 11 is an exploded perspective view of a cooling plate of the system of FIG. 8, according to at least some embodiments of the present disclosure;

FIG. 12 is a broken plan view of a portion of a cooling plate of the system of FIG. 8, according to at least some embodiments of the present disclosure;

FIG. 13 is a perspective view of certain components of the system of FIG. 8, according to at least some embodiments of the present disclosure;

FIG. 14 is a cross-sectional view of a system according to at least some embodiments of the present disclosure; and

FIG. 15 is a flow chart illustrating a method according to at least some embodiments of the present disclosure.

Like reference numbers and designations in the various drawings may indicate like elements.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It is understood that various changes may be made in the function and arrangement of elements without departing from the spirit and scope of the appended claims.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

Various aspects of the present disclosure will be described herein with reference to drawings that are schematic illustrations of idealized configurations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

The present disclosure now will be described more fully hereinafter with reference to the accompanying figures in which some but not all embodiments of the disclosures are shown. Indeed, the present disclosure may be embodied in many different forms and should not be construed as limited to the embodiments set forth herein.

Like numbers refer to like elements throughout. As used herein, terms such as “front,” “rear,” “top,” etc. are used in the examples provided below to describe the position of certain components or portions of components in an installed and operational configuration. As used herein, the term “module” encompasses hardware, software and/or firmware configured to perform one or more particular functions, including but not limited to conversion between electrical and optical signals and transmission of the same. As would be evident to one of ordinary skill in the art in light of the present disclosure, the term “substantially” indicates that the referenced element or associated description is accurate to within applicable engineering tolerances.

As discussed herein, the example embodiment is described with reference to a pluggable connector such as an octal small form factor pluggable (OSFP); however the embodiments of the present disclosure may equally be applicable to a Quad Small Form-factor Pluggable (QSFP) connector as the cable connector or any connector (e.g., Small Form Pluggable (SFP), C-Form-factor Pluggable (CFP), and the like). Moreover, the embodiments of the present disclosure may also be used with any cable (e.g., passive copper cable (PCC), active copper cable (ACC), or the like) or interconnect utilized by datacenter racks and associated switch modules (e.g., an active optical module (AOM), QSFP transceiver module, or the like).

Additionally, as discussed herein, the example embodiment is described with reference to a vertical-cavity surface-emitting laser (VCSEL) as an element of a transceiver system; however, embodiments of the present disclosure may be equally applicable for use with any transceiver system and/or element. Still further, as discussed herein, the example embodiment is described with reference to a switch module configured to receive a cage receptacle assembly to allow signals to pass between a cable connector and the switch module. The present disclosure, however, contemplates that a network interface, a high-capacity adapter, or any other applicable networking interface may equally be used instead or in conjunction with the switch module to receive the cage receptacle.

Embodiments of the present disclosure are contemplated to be deployed in a datacenter environment. While embodiments will be described in connection with certain examples of datacenter environments, it should be appreciated that embodiments of the present disclosure are not so limited. Indeed, embodiments of the present disclosure contemplate the ability to deploy a cage receptacle assembly in any number of environments including a datacenter environment or any other suitable environment in which machine-to-machine communications are facilitated.

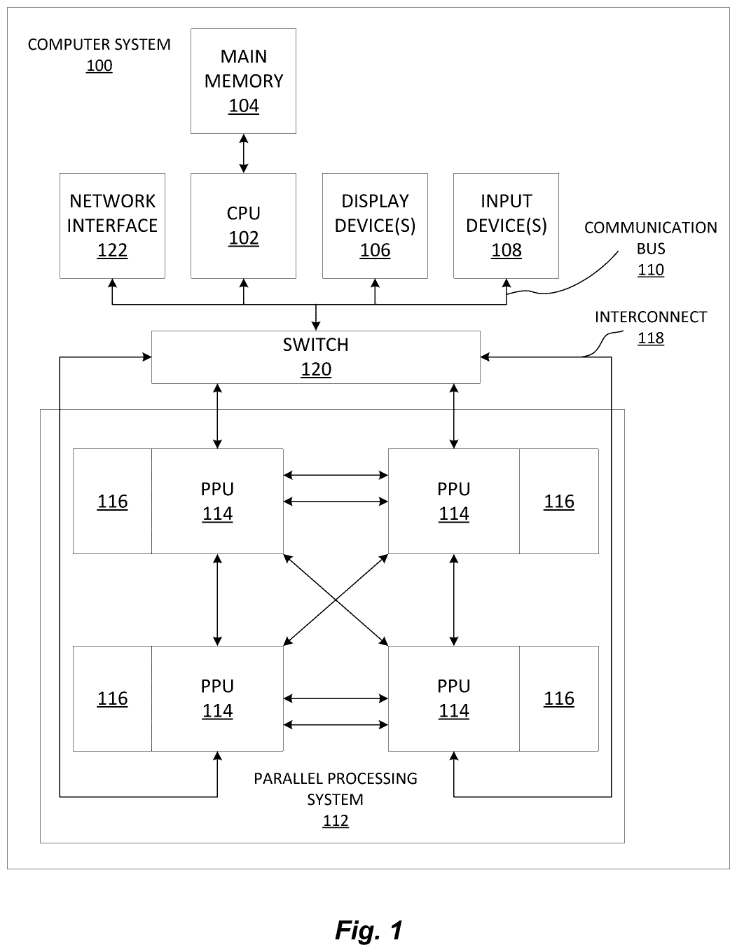

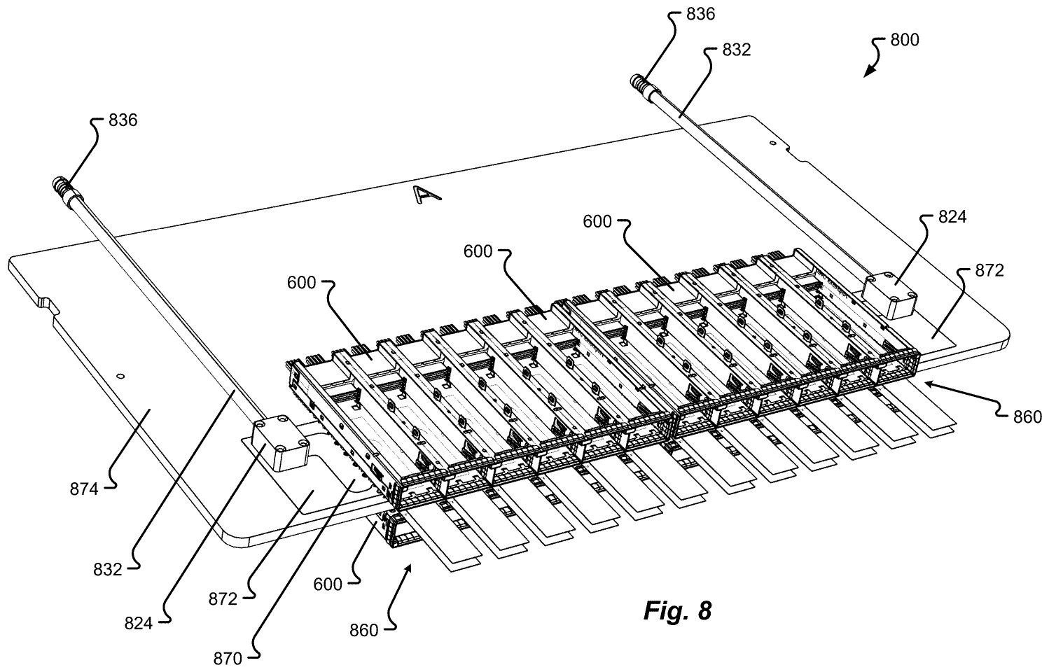

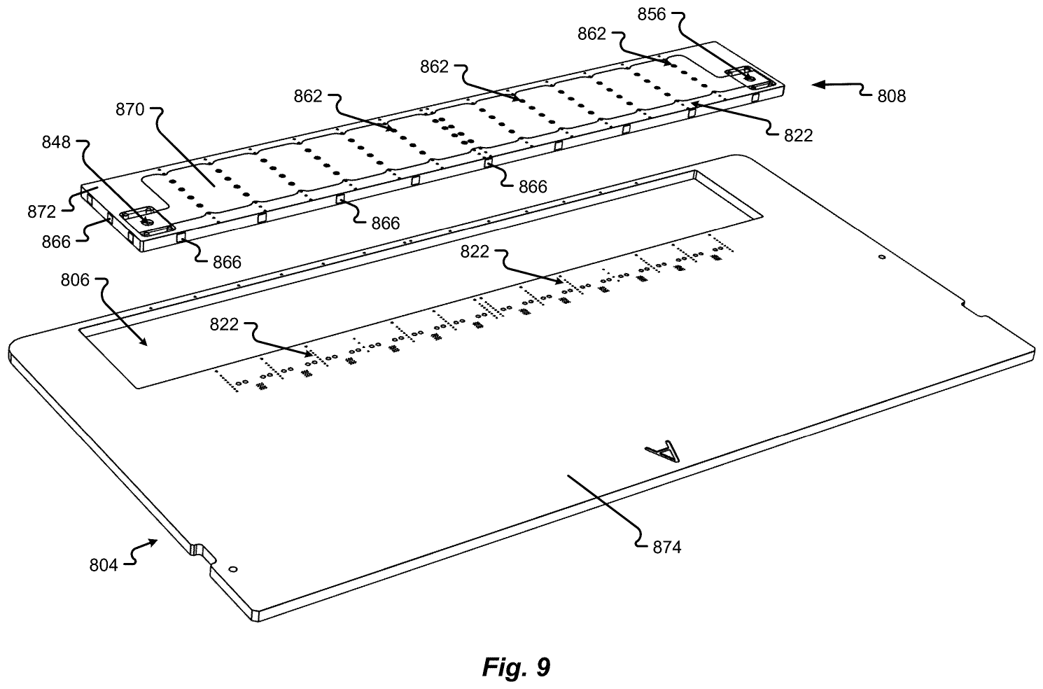

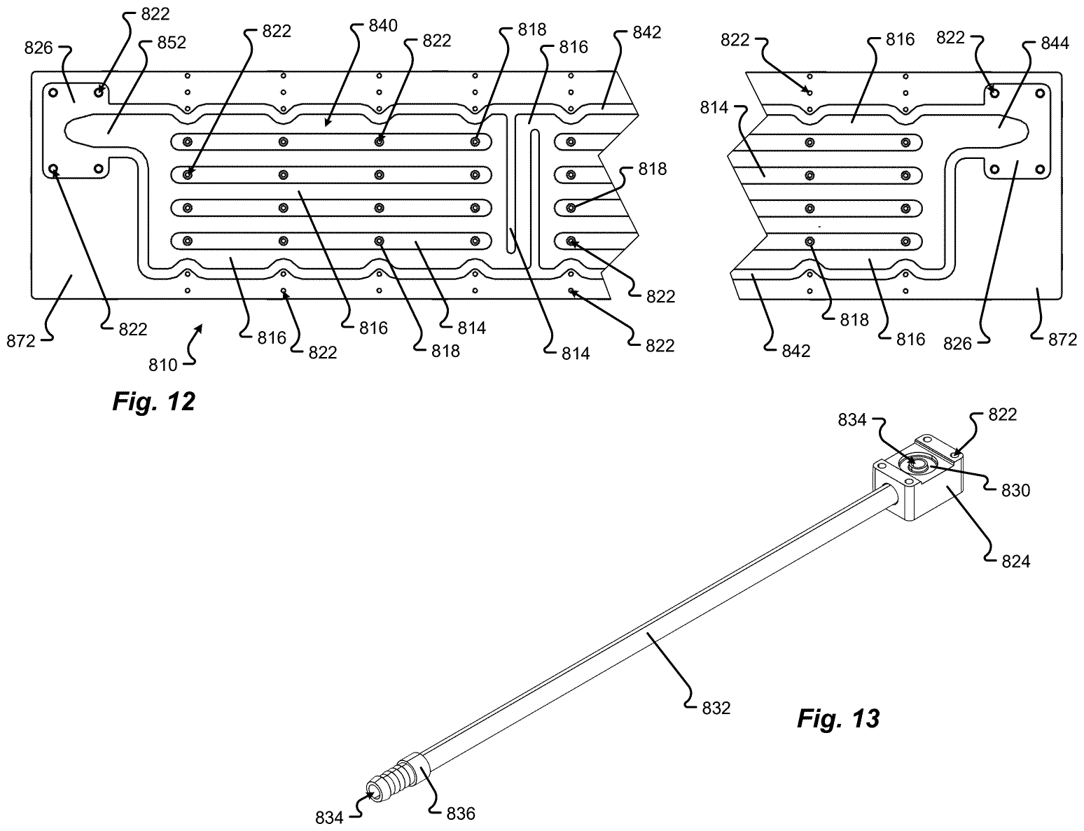

Illustrative datacenter environments and components are shown and will now be described with reference to FIGS. 1 through 15.

FIG. 1 illustrates a computer system 100, according to at least one embodiment. In at least one embodiment, computer system 100 is configured to implement various processes and methods described throughout this disclosure.

In at least one embodiment, computer system 100 comprises, without limitation, at least one central processing unit (“CPU”) 102 that is connected to a communication bus 110 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 100 includes, without limitation, a main memory 104 and control logic (e.g., implemented as hardware, software, or a combination thereof) and data are stored in main memory 104 which may take form of random access memory (“RAM”). In at least one embodiment, a network interface subsystem (“network interface”) 122 provides an interface to other computing devices and networks for receiving data from and transmitting data to other systems from computer system 100.

In at least one embodiment, computer system 100, in at least one embodiment, includes, without limitation, input devices 108, parallel processing system 112, and display devices 106 which can be implemented using a conventional cathode ray tube (“CRT”), liquid crystal display (“LCD”), light emitting diode (“LED”), plasma display, or other suitable display technologies. In at least one embodiment, user input is received from input devices 108 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 104 and/or secondary storage. Computer programs, if executed by one or more processors, enable system 100 to perform various functions in accordance with at least one embodiment. memory 104, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 102; parallel processing system 112; an integrated circuit capable of at least a portion of capabilities of both CPU 102; parallel processing system 112; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 100 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 112 includes, without limitation, a plurality of parallel processing units (“PPUs”) 114 and associated memories 116. In at least one embodiment, PPUs 114 are connected to a host processor or other peripheral devices via an interconnect 118 and a switch 120 or multiplexer. In at least one embodiment, parallel processing system 112 distributes computational tasks across PPUs 114 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 114, although such shared memory may incur performance penalties relative to use of local memory and registers resident to a PPU 114. In at least one embodiment, operation of PPUs 114 is synchronized through use of a command such as syncthreads(), wherein all threads in a block (e.g., executed across multiple PPUs 114) are configured to reach a certain point of execution of code before proceeding.

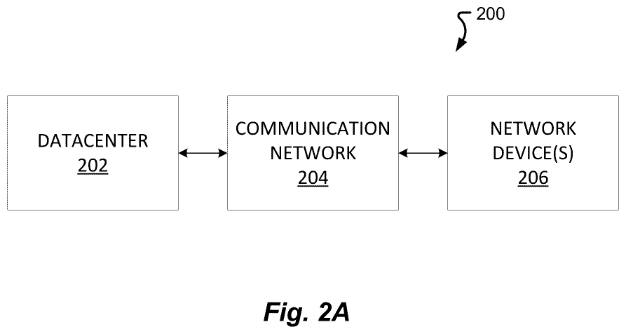

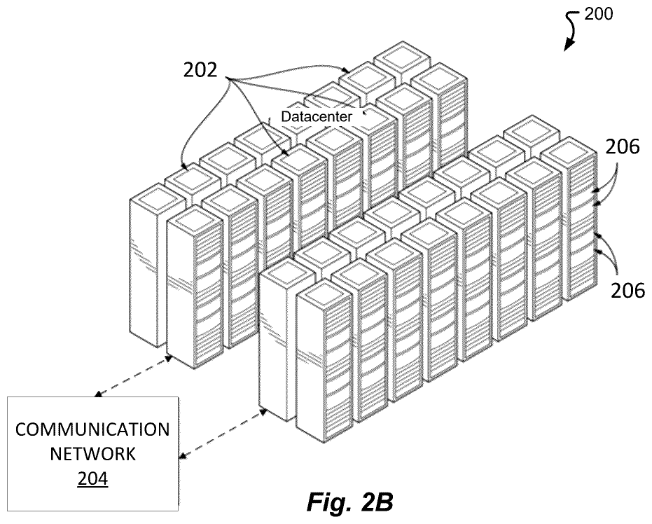

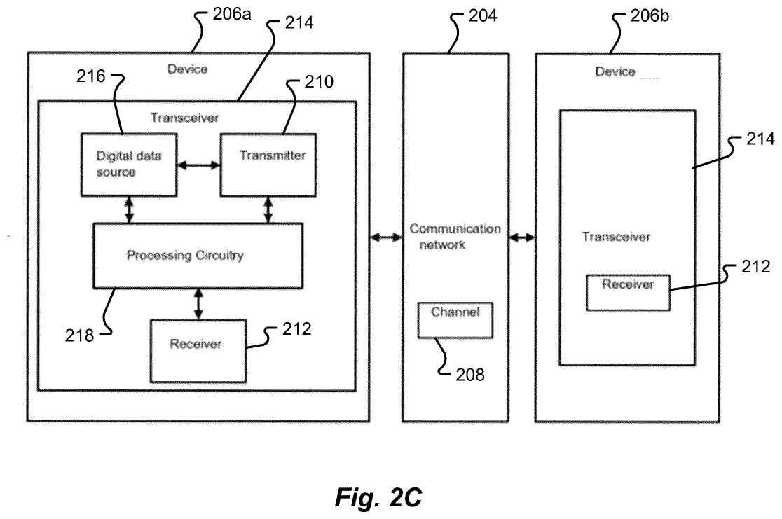

Datacenters, high performance computing clusters, and/or the like are often formed of various computing components or networked devices, and communication networks formed of electrical and/or optical devices may be used to enable communication between the networked devices forming these implementations. As shown in FIGS. 2A, 2B, and 2C, for example, a network architecture 200 may include a datacenter 202, a communication network 204, and network device(s) 206. The network architecture 200 may illustrate a general computing architecture within which more specific systems and/or subsystems may function. Although described hereinafter with reference to a network architecture 200 and/or datacenter 202 within which the embodiments of the present disclosure may be implemented, the present disclosure contemplates that the transceiver resiliency devices and techniques described herein may be applicable to any communication implementation without limitation.

For example, the datacenter 202 may be a centralized facility designed to house computing resources and related components. The datacenter 202 may operate to support the infrastructure required for advanced computational tasks, for efficient, secure, and reliable operations. The datacenter 202 may include the building and structural components, including power supplies, cooling systems, fire suppression systems, and physical security measures that are configured to maintain optimal operating conditions and/or protect the equipment from environmental hazards and unauthorized access. An example datacenter 202 may include high-performance servers or compute nodes, often arranged in racks, such as those illustrated in FIG. 2B, and connected through high-speed networks as described herein. These servers may include processors (e.g., central processing units (CPUs), graphics processing units (GPUs), data processing units (DPUs) and/or the like), memory (e.g., RAM), and storage solutions (e.g., hard disk drives (HDDs), solid state drives (SSDs), and/or the like. The hardware configuration may be designed for parallel processing and high throughput, catering to the demands of high-performance computing (HPC) applications.

In one example, the processors may include central processing units (CPUs), graphics processing units (GPUs), data processing units (DPUs), quantum processing units (QPUs), a plurality of parallel processing units (PPUs), and application-specific integrated circuits (ASICs). QPUs configured to perform one or more operations associated with a quantum algorithm In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU with which the local qubits are associated.

The datacenter 202 may include high-speed network equipment, such as network switches, routers, firewalls, and/or the like to facilitate fast and secure data transmission within the datacenter 202 (e.g., between the servers or compute nodes) and between external networks. The datacenter 202 may facilitate communication between servers or compute nodes through a network topology that ensures efficient data exchange, minimizes latency, and maximizes bandwidth. The network topology may dictate how various network devices, such as switches and routers, are interconnected for data flow. By implementing an effective network topology, the datacenter 202 may support high-performance computing tasks. Examples of various network topologies may include hierarchical networking topologies such as the fat tree topology, Slim Fly topology, Dragonfly topology, and/or the like. The datacenter 202 may adhere to a networking topology (e.g., a hierarchal networking topology), such as a fat tree topology, a Slim Fly topology, a Dragonfly topology, and/or the like. The datacenter 202 routes traffic amongst the network switches and servers therein, and at least one layer of the topology in the datacenter 202 is coupled to the communication network 204 to allow networking traffic to flow between the datacenter 202 and the network device(s) 206.

The communication network 204 may communicably couple the datacenter 202 with network device(s) 206 and other external devices for data exchange and connectivity. Examples of the communication network 204 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. The ability of the communication network 204 to incorporate multiple network types and configurations may allow the datacenter 202 to adapt to diverse application needs, from general data communication to specialized HPC tasks. As described herein, the communication network 204 may leverage various optical components to establish communication links (e.g., communicably couple) between components in the architecture 200. As such, the communication network 204 may include various optical devices, transceivers, modules, and/or the like that are configured to generate optical signals (e.g., provide optical transmitter functionality) and/or receive optical signals (e.g., provide optical receiver functionality).

The network device(s) 206 may include a variety of computing devices capable of transmitting and receiving signals over the communication network 204. The network device(s) 206 may range from personal computing devices to complex server configurations. Examples include Personal Computers (PCs), laptops, tablets, smartphones, and servers. The network device(s) 206 may facilitate user interactions with the datacenter 202, allowing for data input, retrieval, and processing from remote locations. In addition to individual computing devices, the network device(s) 206 may also include collections of servers or additional datacenters. For instance, these could be other datacenters similar to or the same as datacenter 202. Such an interconnection may allow for the formation of a distributed computing environment for improved redundancy, load balancing, and disaster recovery capabilities. By linking multiple datacenters, the network architecture 200 may leverage geographically dispersed resources, optimizing performance and ensuring high availability.

As described herein, the datacenter 202 and/or the network device(s) 206 may include storage devices and processing circuitry for executing computing tasks, such as controlling the flow of data internally and over the communication network 204. The processing circuitry may include software, hardware, or a combination thereof. For example, the processing circuitry may include a memory containing executable instructions and a processor (e.g., a microprocessor) that executes these instructions. The memory may correspond to any suitable type of memory device or collection of memory devices configured to store instructions. Non-limiting examples of suitable memory devices include Flash memory, Random Access Memory (RAM), Read Only Memory (ROM), variants thereof, combinations thereof, or similar technologies. In specific embodiments, the memory and processor may be integrated into a common device, such as a microprocessor with integrated memory. Additionally, or alternatively, the processing circuitry may comprise hardware components, such as an application-specific integrated circuit (ASIC). Other non-limiting examples of processing circuitry include Integrated Circuit (IC) chips, CPUs, GPUs, microprocessors, Field Programmable Gate Arrays (FPGAs), collections of logic gates or transistors, resistors, capacitors, inductors, and diodes. Some or all of the processing circuitry may be provided on a Printed Circuit Board (PCB) or a collection of PCBs. It should be appreciated that any appropriate type of electrical component or collection of electrical components may be suitable for inclusion in the processing circuitry.

In addition, although not explicitly shown, the present disclosure contemplates that the datacenter 202 and network device(s) 206 may include one or more communication interfaces for facilitating wired and/or wireless communication between one another and other unillustrated elements of the network architecture 200. These communication interfaces may include a variety of technologies, including but not limited to Ethernet ports, fiber optic connections, Wi-Fi® transceivers, Bluetooth® modules, and cellular communication modules for integration and interoperability among the various components within the network architecture 200.

Furthermore, the present disclosure contemplates that the network architecture 200 may include additional components and functionalities. For example, the network architecture may include, without limitation, additional processing units, specialized accelerators (such as Tensor Processing Units or TPUs), enhanced security modules, and redundant power supplies. The inclusion of these elements may be intended to ensure that the network architecture 200 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the network architecture 200.

In high-capacity datacenter networks, the communication network 204 may leverage optical transceivers that transmit and receive optical signals over optical fibers or other optical communication mediums to establish connection between devices in the architecture 200.

As shown in FIG. 2C, in one specific but non-limiting example, the communication network 204 is a network that enables data transmission between the devices 206a and 206b using data signals (e.g., digital, optical, wireless signals).

Each type of network offers specific advantages tailored to different operational requirements. For instance, an IP network or Ethernet network may provide widespread compatibility and ease of integration, supporting various protocols and applications across the datacenter 202 and the network device(s) 206 (and/or external devices). An InfiniBand network may offer high throughput and low latency, ideal for HPC environments where rapid data transfer and minimal delay are required. Fibre Channel networks may be employed for their robust performance in storage area networks (SANs), ensuring fast and reliable access to storage resources. Cellular and wireless communication networks may be used to extend connectivity to remote or mobile devices for increased flexibility and accessibility.

As noted above, the network devices 206a, 206b may include one or more of Personal Computer (PC), a laptop, a tablet, a smartphone, a server, a collection of servers, and/or any suitable computing device for sending and receiving signals over the communication network 204. In at least one example embodiment, the one or more network devices 206 correspond to another datacenter, similar to or the same as datacenter 202.

Each network device 206 may be provided with transmitter functionality 210, receiver functionality 212, and/or transceiver functionality 214. The transmitter functionality 210, receiver functionality 212, and/or transceiver functionality 214 may include hardware and/or software to support the sending and/or receiving of data across the communication network 204, through one or more communication channels 208, for example.

A network device 206 may also include a digital data source 216 and/or processing circuitry 218 to support interactions within the transceiver 214 or to support interactions between components of the transceiver 214 and other components of the device 206. For instance, the processing circuitry 218 may be included in the transceiver 214 as illustrated or may be external to the transceiver 214, without departing from the scope of the present disclosure.

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

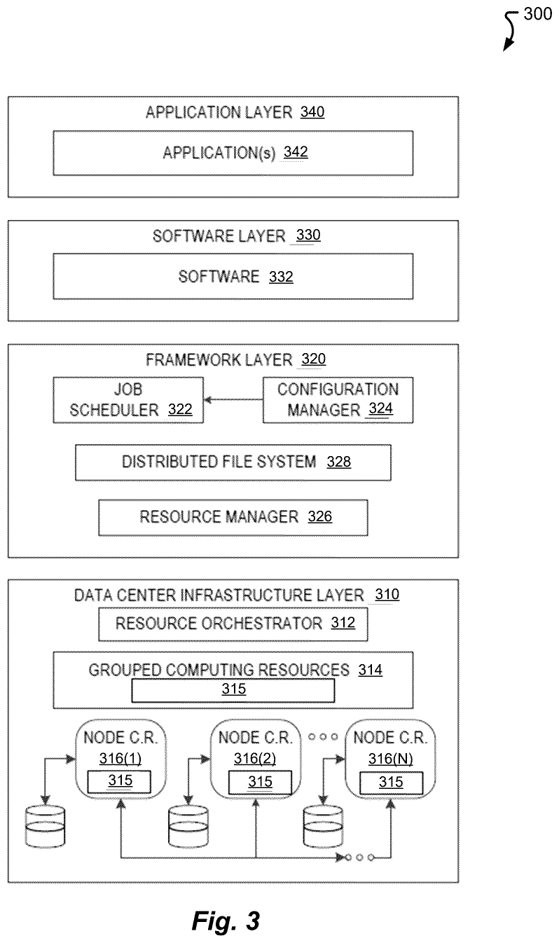

FIG. 3 illustrates additional components of an example datacenter 300 according to at least some embodiments of the present disclosure. The datacenter 300 may also include one or more modules subject to one or more cooling/thermal management features as described herein.

In at least one embodiment, datacenter 300 includes a datacenter infrastructure layer 310, a framework layer 320, a software layer 330, and an application layer 340. In at least one embodiment, the infrastructure layer 310, the framework layer 320, the software layer 330, and the application layer 340 may be partly or fully provided via computing components on server trays located in racks of the datacenter 300 (or of another datacenter, such as the datacenter 202). This enables cooling systems of the present disclosure to direct cooling to certain ones of the computing features and the interconnect features, in an efficient and effective manner. Further, aspects of the datacenter 300, including the datacenter infrastructure layer 310, the framework layer 320, the software layer 330, and the application layer 340 may be used to support selection or design of the intermediate layers. As such, the discussion in reference to FIG. 3 may be understood to apply to the hardware and software features required to enable or support cooling functionality, for instance.

In at least one embodiment, as in FIG. 3, datacenter infrastructure layer 310 may include a resource orchestrator 312, grouped computing resources 314, and node computing resources (“node C.R. s”) 316(1)-316(N), where “N” represents any whole, positive integer. In at least one embodiment, node C.R. s 316(1)-316(N) may include, but are not limited to, any number of central processing units (“CPUs”) or other processors (including accelerators, field programmable gate arrays (FPGAs), graphics processors, etc.), memory devices (such as dynamic read-only memory), storage devices (such as solid state or disk drives), network input/output (“NW I/O”) devices, network switches, virtual machines (“VMs”), power modules, and cooling modules, etc. In at least one embodiment, one or more node C.R. s from among node C.R. s 316(1)-316(N) may be a server having one or more of above-mentioned computing resources.

In at least one embodiment, grouped computing resources 314 may include separate groupings of node C.R. s housed within one or more racks (not shown), or many racks housed in datacenters at various geographical locations (also not shown). Separate groupings of node C.R. s within grouped computing resources 314 may include grouped compute, network, memory or storage resources that may be configured or allocated to support one or more workloads. In at least one embodiment, several node C.R. s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 312 may configure or otherwise control one or more node C.R. s 316(1)-316(N) and/or grouped computing resources 314. In at least one embodiment, resource orchestrator 312 may include a software design infrastructure (“SDI”) management entity for datacenter 300. In at least one embodiment, resource orchestrator may include hardware, software or some combination thereof.

In at least one embodiment, as shown in FIG. 3, framework layer 320 includes a job scheduler 322, a configuration manager 324, a resource manager 326 and a distributed file system 328. In at least one embodiment, framework layer 320 may include a framework to support software 332 of software layer 330 and/or one or more application(s) 342 of application layer 340. In at least one embodiment, software 332 or application(s) 342 may respectively include web-based service software or applications, such as those provided by Amazon Web Services, Google Cloud and Microsoft Azure. In at least one embodiment, framework layer 320 may be, but is not limited to, a type of free and open-source software web application framework such as Apache Spark™ (hereinafter “Spark”) that may utilize distributed file system 328 for large-scale data processing (such as “big data”). In at least one embodiment, job scheduler 322 may include a Spark driver to facilitate scheduling of workloads supported by various layers of datacenter 300. In at least one embodiment, configuration manager 324 may be capable of configuring different layers such as software layer 330 and framework layer 320 including Spark and distributed file system 328 for supporting large-scale data processing. In at least one embodiment, resource manager 326 may be capable of managing clustered or grouped computing resources mapped to or allocated for support of distributed file system 328 and job scheduler 322. In at least one embodiment, clustered or grouped computing resources may include grouped computing resource 314 at datacenter infrastructure layer 310. In at least one embodiment, resource manager 326 may coordinate with resource orchestrator 312 to manage these mapped or allocated computing resources.

In at least one embodiment, software 332 included in software layer 330 may include software used by at least portions of node C.R. s 316(1)-316(N), grouped computing resources 314, and/or distributed file system 328 of framework layer 320. One or more types of software may include, but are not limited to, Internet web page search software, e-mail virus scan software, database software, and streaming video content software.

In at least one embodiment, application(s) 342 included in application layer 340 may include one or more types of applications used by at least portions of node C.R. s 316(1)-316(N), grouped computing resources 314, and/or distributed file system 328 of framework layer 320. One or more types of applications may include, but are not limited to, any number of a genomics application, a cognitive compute, and a machine learning application, including training or inferencing software, machine learning framework software (such as PyTorch, TensorFlow, Caffe, etc.) or other machine learning applications used in conjunction with one or more embodiments.

In at least one embodiment, any of configuration manager 324, resource manager 326, and resource orchestrator 312 may implement any number and type of self-modifying actions based on any amount and type of data acquired in any technically feasible fashion. In at least one embodiment, self-modifying actions may relieve a datacenter operator of datacenter 300 from making possibly bad configuration decisions and possibly avoiding underutilized and/or poor performing portions of a datacenter.

In at least one embodiment, datacenter 300 may include tools, services, software or other resources to train one or more machine learning models or predict or infer information using one or more machine learning models according to one or more embodiments described herein. In at least one embodiment, a machine learning model may be trained by calculating weight parameters according to a neural network architecture using software and computing resources described above with respect to datacenter 300. In at least one embodiment, trained machine learning models corresponding to one or more neural networks may be used to infer or predict information using resources described above with respect to datacenter 300 by using weight parameters calculated through one or more training techniques. Deep learning may be advanced using any appropriate learning network and the computing capabilities of the datacenter 300. As such, a deep neural network (DNN), a recurrent neural network (RNN) or a convolutional neural network (CNN) may be supported either simultaneously or concurrently using the hardware in the datacenter. Once a network is trained and successfully evaluated to recognize data within a subset or a slice, for instance, the trained network can provide similar representative data for using with the collected data.

In at least one embodiment, datacenter 300 may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or perform inferencing of information, such as pressure, flow rates, temperature, and location information, or as any other artificial intelligence service.

Inference and/or training logic 315 may be used to perform inferencing and/or training operations associated with one or more embodiments. In at least one embodiment, inference and/or training logic 315 may be used in a datacenter 300 (whether in grouped computing resources 314, in one or more node C.R. s 316(1)-316(N), or elsewhere) or in other systems described herein, for inferencing or predicting operations based, at least in part, on weight parameters calculated using neural network training operations, neural network functions and/or architectures, or neural network use cases described herein. In at least one embodiment, inference and/or training logic 315 may include, without limitation, hardware logic in which computational resources are dedicated or otherwise exclusively used in conjunction with weight values or other information corresponding to one or more layers of neurons within a neural network. In at least one embodiment, inference and/or training logic 315 may be used in conjunction with an application-specific integrated circuit (ASIC), such as a Tensorflow® Processing Unit from Google, an inference processing unit (IPU) from Graphcore™, or a Nervana® (such as “Lake Crest”) processor from Intel Corp.

In at least one embodiment, inference and/or training logic 315 may be used in conjunction with central processing unit (CPU) hardware, graphics processing unit (GPU) hardware or other hardware, such as field programmable gate arrays (FPGAs). In at least one embodiment, inference and/or training logic 315 includes, without limitation, code and/or data storage modules which may be used to store code (such as graph code), weight values and/or other information, including bias values, gradient information, momentum values, and/or other parameter or hyperparameter information. In at least one embodiment, each of the code and/or data storage modules is associated with a dedicated computational resource. In at least one embodiment, the dedicated computational resource includes computational hardware that further include one or more ALUs that perform mathematical functions, such as linear algebraic functions, only on information stored in code and/or data storage modules, and results from which are stored in an activation storage module of the inference and/or training logic 315.

The switches within each layer (e.g., edge layer, aggregation layer, core layer) may be 1U switches. The switches may be electrical switches, optical switches, hybrid electro-optical switches, or any combination thereof. The switches may be implemented with suitable hardware and/or software that enables the routing of signals in the appropriate domain. For example, an electrical switch may include receivers that receive and convert optical signals into electrical signals for routing within the electrical switch. A receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In some embodiments, receiver/transmitter pairs may be integrated into a single transceiver. Each electrical switch may also include internal switching circuitry for routing electrical signals within the electrical switch.

A switch, whether electric, optoelectronic, and/or quantum, may include input circuit(s) and output circuit(s), linked by switching core. In some embodiments, a switch may include multiple inputs and outputs.

A number of architectures of this type have been proposed, including “Next Generation I/O” (NGIO) and “Future I/O” (FIO), culminating in the “InfiniBand” architecture, which has been advanced by a consortium led by a group of industry leaders (including Intel, Sun, Hewlett Packard, IBM, Compaq, Dell and Microsoft). Storage Area Networks (SAN) provide a similar, packetized, serial approach to high-speed storage access, which can also be implemented using an InfiniBand fabric.

Communications between a parallel bus and a packet network generally require a communications interface, to convert bus cycles into appropriate packets and vice versa. For example, a host channel adapter or target channel adapter can be used to link a parallel bus, such as the PCI bus, to the InfiniBand fabric. When the adapter receives data from a device on the PCI bus, it inserts the data in the payload of an InfiniBand packet, and then adds an appropriate header and error checking code, such as a cyclic redundancy check (CRC) code, as required for network transmission. The InfiniBand packet header includes a routing header and a transport header. The routing header contains information at the data link protocol level, including fields required for routing the packet within and between fabric subnets. The transport header contains higher-level, end-to-end transport protocol information. Similar headers are used in other types of packet networks known in the art, such as Internet Protocol (IP) networks.

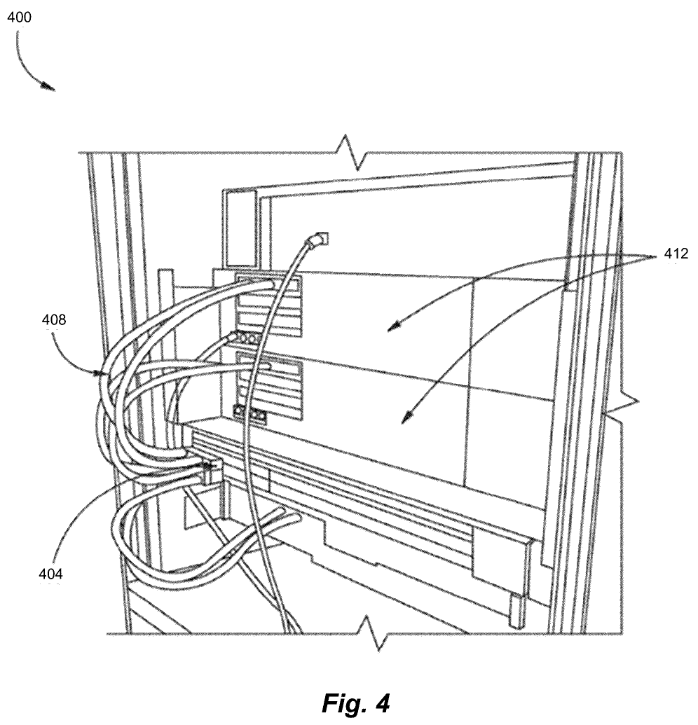

FIG. 4 illustrates an example datacenter rack 400, or cabinet that is designed to house servers, networking devices, modules, and other datacenter 202 computing equipment and used in conjunction with optical fibers 408.

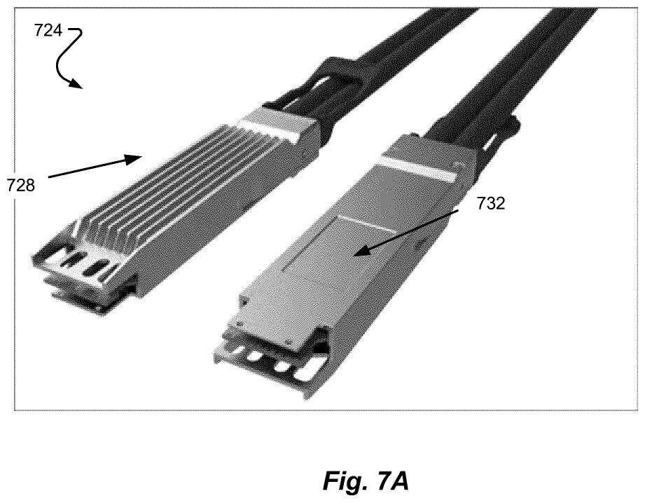

Different types of cable connectors, such as those illustrated in FIGS. 7A and/or 7B, exist for enabling transmission of signals (optical and/or electrical) between switch modules and other equipment in a datacenter. For example, OSFP connectors and cables, as well as other forms of connectors such as QSFP, Small Form Pluggable (SFP), and C-Form-factor Pluggable (CFP) connectors provide high-speed information operations interface interconnects. Regardless of the type of cable connectors, these transceivers may interface a switch system board, such as a motherboard in a switch system, to a fiber optic or copper networking cable, such as by making connections between switch modules 412 as shown in FIG. 4.

With continued reference to FIG. 4, for example, a switch module 412 (or other interconnect module), which may house an application-specific integrated circuit (ASIC) as well as other internal components (not visible), is typically incorporated into a datacenter 202 or 300 via connections to other switch systems, servers, racks, and network components. A switch module 412 may, for example, interact with other components of the datacenter 202 or 300 via external optical cables 408 and possible transceiver systems housed in the end of an optical cable 408. These optical cables 408 and transceivers may allow connections between a switch module 412 and the other components of the datacenter 202 or 300 via cage receptacle assemblies 404.

The switch modules 412 may be configured to be received by a datacenter rack 400 and may be configured to allow for the conversion between optical signals and electrical signals. For example, optical cables 408 may carry optical signals as inputs to the switch module 412. The optical signals may be converted to electrical signals via an opto-electronic transceiver assembly, which may form part of the optical cable 408 in cases in which the optical cable 408 is an Active Optical Cable (AOC), such as a cable that includes an OSFP connector that is received by a port of a switch module 412. In other cases, the optical cable 408 may be passive, and the switch module 412 may include opto-electronic components that convert between optical signals and electrical signals. The electrical signals may then be processed by the switch module 412 and/or routed to other computing devices, such as servers and devices on other racks or at other datacenters via other components and cables (not shown). In addition, electrical signals received from other networking devices (e.g., from other datacenters, racks, etc.) may be processed by the switch module 412 and then converted into corresponding optical signals to be transmitted via the optical cables 408, going the opposite direction.

The transmission of data as electrical signals and the conversion between optical signals and electrical signals (e.g., via an AOC and associated transceiver system or AOM) often results in the generation of heat by the components of the datacenter rack 400. As can be appreciated, higher temperatures associated with such heat emissions can correspond to the increased likelihood of failure of electrical components and/or changes in the electrical and/or optical operating parameters of the components resulting in interference with the corresponding electrical and/or optical signals. Additionally, localization or concentration of higher temperatures in electrical components (e.g., the bottom surface of the AOC, AOM, or pluggable cable connector) can result in a further increase in the likelihood of failure of electrical components located near the area of heat concentration.

Accordingly, embodiments of the disclosure described herein provide a cage receptacle assembly that is configured to provide increased thermal efficiency by allowing the heat dissipation units to be independently adjustable relative to the cage body (e.g., “floating”), so that their spatial position and orientation state is aligned with the position and orientation of the respective top or bottom surfaces of the plugged transceiver to achieve effective heat transfer from the transceiver surfaces to the heat dissipation elements. In embodiments, the contact area between the transceiver and heat dissipation unit(s) is enlarged to allow for more surface area of the transceiver contacting the heat dissipation unit(s) to distribute heat more evenly and/or to more effectively dissipate the heat to the surrounding environment to maintain lower temperatures in the components.

It should further be noted that a cable 408 (and similarly the other active optical cables described herein) and connectors may be designed to comply with any applicable standard, for example Ethernet and InfiniBand standards, such as Ethernet variants 200GBASE-FR4, 400GBASE-FR4, and 100GBASE-LR4 to support four wavelengths. Connections between the cable 408 and the switch module 412 may be facilitated by one or more of a transceiver module and a cage receptacle assembly.

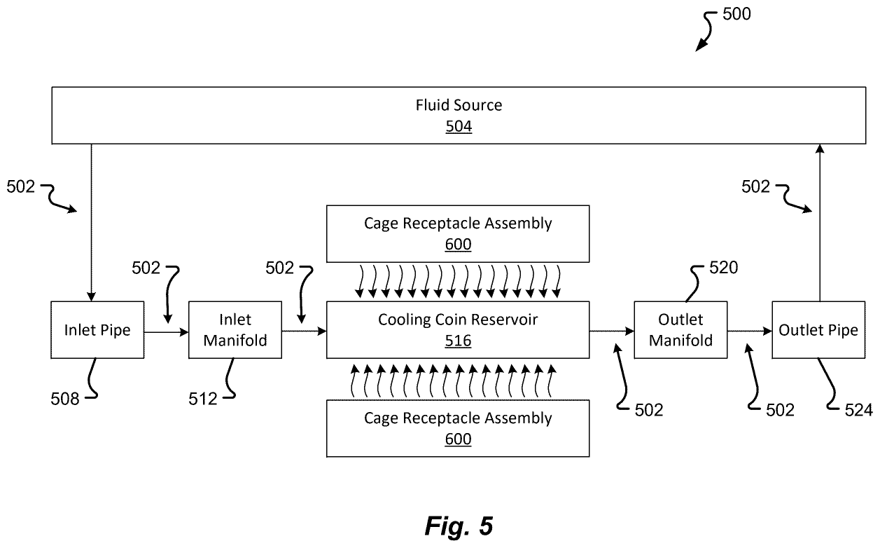

With reference now to FIG. 5, a block diagram of a system 500 will be described in accordance with at least some embodiments of the present disclosure.

The system 500 comprises a fluid flow path 502 that begins and ends at a fluid source 504. The fluid source 504 may comprise a pressurized or unpressurized tank holding a heat transfer fluid. The fluid source 504 may be or comprise a heat sink. In some embodiments, the fluid source 504 may be a natural or manmade body of water, such as a pond, lake, stream, river, or ocean. In some embodiments, the fluid source 504 is actively cooled, using a presently known or yet-to-be-discovered cooling system. In other embodiments, the fluid source 504 is passively cooled, for example by virtue of being located within a natural or manmade heat sink (e.g., an ocean, a reservoir, soil). The fluid source may contain any liquid or gas heat transfer fluid, such as water, carbon dioxide, ammonia, hydrocarbons, hydrofluoroolefins, hydrofluorocarbons, hydrofluoroethers, and/or any combination thereof. The fluid source may contain a heat transfer fluid that will not harm electronic components if the heat transfer fluid leaks from the system 500, such as deionized water or another dielectric fluid. The heat transfer fluid generally includes water, water solutions (e.g. propylene glycol-water), brine, antifreeze, a mixture of antifreeze and water, oil, alcohol, mercury or the like or any other suitable heat conductive fluid. The heat transfer fluid may be an electrically conductive cooling liquid and may include water, deionized water, or a coolant such as R-134a, a mixture of water and additives, such as a mixture of water and ethylene glycol or a mixture of water and propylene glycol e.g. a 25% concentration of propylene glycol in deionized water. The heat transfer fluid may also be a dielectric fluid alone (e.g., not having water for purposes of this disclosure) or a water in combination with an additive including at least one dielectric fluid, such as or one or more of de-ionized water, ethylene glycol, and propylene glycol. In at least one embodiment, the heat transfer fluid may be an absorption chiller having a working fluid being a mixed solution containing lithium bromide as the absorbent material and water as the carrier material. The heat transfer fluid may also be a two-phase coolant that has a boiling point that is below the expected operating temperature of the electronic devices. Exemplary two-phase coolants include 2, 3, 3, 3-tetrafluoropropene, 1, 1, 1, 2-tetrafluoroethane and water.

Although the fluid source 504 is shown in FIG. 5 as a single component, in some embodiments a plurality of fluid sources 504 may be used, such as a first fluid source 504 to provide fluid into the fluid flow path 502, and a second fluid source 504 to receive fluid that has already passed through the fluid flow path 502. In such embodiments, the first fluid source 504 and the second fluid source 504 may or may not be in fluid communication one with another.

The system 500 comprises an inlet pipe 508 (which may also be referred to as an intake pipe) and an outlet pipe 524 (which may also be referred to as a discharge pipe). Each of the inlet pipe 508 and the outlet pipe 524 may be any pipe, tube, hose, line, duct, or other conduit suitable for transporting heat transfer fluid from or to the fluid source 504. In embodiments where the fluid flow path 502 is pressurized, the inlet pipe 508 and the outlet pipe 524 may be any pipe, tube, hose, line, duct, or other conduit suitable for transporting pressurized fluid from or to the fluid source 504, at the appropriate pressure.

The inlet pipe 508 and the outlet pipe 524 may be any length and diameter required to connect the inlet manifold 512 and the outlet manifold 520, respectively, to the fluid source 504, and to transport heat transfer fluid from one component to another at the appropriate flow rate, volume, pressure, purity, etc. Each of the inlet pipe 508 and the outlet pipe 524 may comprise multiple sections, with each section comprising the same or a different material as another section, with the same or different dimensions, specifications, characteristics, and/or qualities. The inlet pipe 508 and the outlet pipe 524 may each comprise one or more connectors, fittings, valves, pumps, gaskets, filters, nozzles, and/or other components useful for transporting heat transfer fluid from one location to another and delivering that fluid with the appropriate qualities and characteristics (e.g., the appropriate flow rate, volume, pressure, purity, etc.).

The inlet manifold 512 connects the inlet pipe 508 to the cooling coin pathway 516, such that the cooling coin pathway 516 is in fluid communication with the fluid source 504 via the inlet pipe 508. The inlet manifold 512 may, in some embodiments, be permanently or removably secured to a cooling coin or other structure that defines the cooling coin pathway 516. The inlet manifold 512 is configured to route fluid received via the inlet pipe 508 to an inlet or intake port of the cooling coin pathway 516. Accordingly, the inlet manifold 512 may comprise, in at least some embodiments of the present disclosure, a first fitting adapted to receive the inlet pipe 508; a second fitting configured to connect to the inlet or intake port of the cooling coin pathway 516; and an internal channel or flow path configured to route fluid from the first fitting to the second fitting. The inlet manifold 512 may comprise one or more gaskets, seals (e.g., o-rings), or other components configured to eliminate or minimize leakage of fluid from the connection points between the inlet pipe 508 and the inlet manifold 512, and/or between inlet manifold 512 and the cooling coin pathway 516, ensuring the system's reliability and safety.

The cooling coin pathway 516 is configured to route fluid along an internal flow path so that the fluid can absorb heat generated at or by one or a plurality of cage receptacle assemblies or cages 600 mounted adjacent the cooling coin pathway 516. In some embodiments, the cooling coin pathway 516 comprises a single uninterrupted tank or receptacle, such that fluid entering the cooling coin pathway 516 can flow unimpeded to any other part of the cooling coin pathway 516 before exiting the cooling coin pathway 516 into the outlet manifold 520. In other embodiments, the cooling coin pathway 516 comprises a single internal conduit or channel that directs fluid along a specific flow path from entry into the cooling coin pathway 516 through the inlet manifold 512 until exit from the cooling coin pathway 516 into the outlet manifold 520. In such embodiments, the single internal conduit or channel may be configured to route fluid back and forth along a length of the cooling coin pathway 516 one or more times prior to exiting the cooling coin pathway 516; or to route fluid back and forth along a width of the cooling coin pathway one or more times prior to exiting the cooling coin pathway 516; or to route fluid along any other flow path within the cooling coin pathway 516. In some embodiments, the internal conduit or channel may be designed to provide even or substantially even cooling (e.g., even absorption of heat by the fluid within the cooling coin pathway 516) along a length and/or a width of the cooling coin pathway 516, so as to provide approximately the same level of cooling to all of the cage receptacle assemblies or cages 600 mounted adjacent the cooling coin pathway 516.

The cooling coin pathway 516 may in some embodiments comprise a plurality of channels defining a plurality of flow paths through which fluid may traverse the cooling coin pathway 516. Two or more of the plurality of flow paths may be parallel to each other, and/or may have portions that are parallel to each other.

In any embodiment of the cooling coin pathway 516 that comprises one or more channels, the walls or other structure that define the channel may provide structural support for the cooling coin in which the pathway is located.

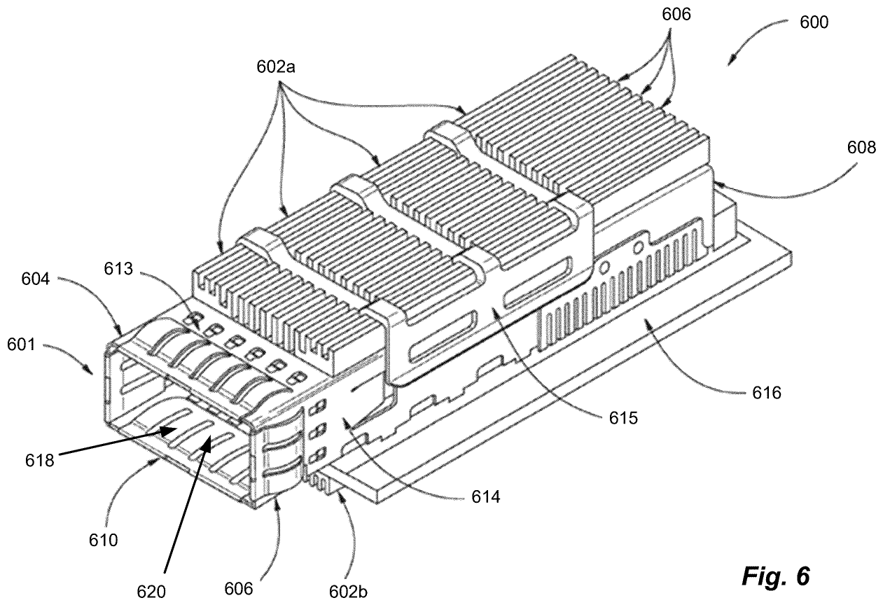

The cage receptacle assemblies 600 may, in some embodiments, be mounted directly to a cooling coin in which the cooling coin pathway 516 is located. In such embodiments, the cage receptacle assemblies 600 may be mounted to the cooling coin using one or more fasteners. In some embodiments, the fasteners may be fashioned of metal or another heat-conductive material. The fasteners may extend into the cooling coin, which may facilitate heat transfer from the cage receptacle assemblies 600 to the cooling coin and thus to the fluid within the cooling coin pathway 516. The fasteners may engage the cooling coin via a press fit (e.g., a friction fit or an interference fit), or may screw into the cooling coin, or may snap into the cooling coin, or may engage the cooling coin in any other manner sufficient to secure the cage receptacle assemblies 600 to the cooling coin. Heat and/or pressure may be used when securing the cage receptacle assemblies 600 to the cooling coin. The fasteners may be or comprise, for example, screws, nails, clips, staples, clamps, and/or pins. The fasteners may be integral with or separate from the cage receptacle assemblies 600. Also in some embodiments, the cage receptacle assemblies 600 may comprise one or more features (e.g., fins) configured to dissipate heat from the cage receptacle assemblies 600 and/or to transfer heat away from the cage receptacle assemblies 600. More details of the cage receptacle assemblies 600 are provided elsewhere herein, including in the discussion of FIG. 6.

The outlet manifold 520 connects the cooling coin pathway 516 to the outlet pipe 524, such that the cooling coin pathway 516 is in fluid communication with the fluid source 504 via the outlet pipe 524. The outlet manifold 520 may, in some embodiments, be permanently or removably secured to a cooling coin or other structure that defines the cooling coin pathway 516. The outlet manifold 520 is configured to route fluid received from the cooling coin pathway 516 via an outlet or discharge port of the cooling coin pathway 516 to the outlet pipe 524. Accordingly, the outlet manifold 520 may comprise, in at least some embodiments of the present disclosure, a first fitting adapted to connect to an outlet or discharge port of the cooling coin pathway 516; a second fitting configured to receive the outlet pipe 524; and an internal channel or flow path configured to route fluid from the first fitting to the second fitting. The outlet manifold 520 may comprise one or more gaskets, seals, or other components configured to eliminate or minimize leakage of fluid from the connection points between the outlet pipe 524 and the outlet manifold 520, and/or between outlet manifold 520 and the cooling coin pathway 516.

When the system 500 is operated, cool fluid from the fluid source 504 enters the fluid flow path 502 by passing through the inlet pipe 508 and the inlet manifold 512 into the cooling coin pathway 516, where it absorbs heat produced by the cage receptacle assemblies 600 mounted adjacent the cooling coin pathway 516. The warmed fluid exits the cooling coin pathway 516 into the outlet manifold 520 and the outlet pipe 524, before returning to the fluid source 504. Where the fluid source 504 is itself a heat sink, or is provided with cooling, the warmed fluid may be cooled upon return to the fluid source 504 before being recirculated through the flow path 502. Where the fluid source 504 is not a heat sink and/or is not otherwise equipped to cool the warmed fluid, the flow path 502 may comprises one or more additional components (e.g., a pump, compressor, fan, radiator or other heat exchangers, expander, condenser, etc.) configured to enable the extraction of heat from the warmed heat transfer fluid prior to the fluid's return to the fluid source 504.

Although the system 500 is shown with a single inlet pipe 508, inlet manifold 512, outlet manifold 520, and outlet pipe 524, in some embodiments of the present disclosure systems such as the system 500 may comprise two or more inlet pipes 508 and/or inlet manifolds 512, and/or two or more outlet manifolds 520 and/or outlet pipes 524. In such embodiments, all of the inlet pipes 508 and the outlet pipes 524 may be configured to receive fluid from and to discharge fluid to, respectively, a single fluid source 504. Alternatively, all of the inlet pipes 508 may be configured to receive fluid from a first fluid source 504 and all of the outlet pipes 524 may be configured to discharge fluid into a second fluid source 504. As yet another alternative, each inlet pipe 508 and each outlet pipe 524 may be configured to receive fluid from or discharge fluid to, as appropriate, a separate fluid source 504.

FIG. 6 illustrates one example of a cage receptacle assembly 600 (also referred to herein simply as a cage 600). The cage assembly receptacle assembly 600 is shown to include a cage body 601.

The cage body 601 of the cage 600 may be defined by a top cage member 604 that defines a top portion 613 and two side portions 614 that extend between the top portion 613 of the top cage member 604 to a bottom cage member 606. The top cage member 604 may be configured to attach to the bottom cage member 606 to form the cage body 601. The cage body 601 of the cage 600 may be configured to at least partially receive a cable connector 724 (also referred to herein as a connector plug 724) as illustrated in FIG. 7A or 7B (e.g., a QSFP cable and/or connector) such that a top surface 728 of the cable connector 724 is disposed proximate the top cage member 604 and a bottom surface 732 of the cable connector 724 is disposed proximate the bottom cage member 606.

The cage 600 may also define a first end 610 and a second end 608 opposite the first end 610, where the first end 610 is configured to receive a cable connector such as the cable connector 724 illustrated in FIGS. 7A-7B. For example, the first end 610 of the cage 600 may be defined such that at least a portion of the cable connector 724 may be inserted into the cage 600, or otherwise brought into engagement or contact with an inner surface 618 of cage body 601 via the first end 610. The first end 610 may be configured to receive a cable connector 724 of any suitable dimension or of any suitable type (e.g., AOC, Ethernet, Direct Attach Copper, etc.) such that the top cage member 604 is located proximate to the top surface 728 of the cable connector 724 and the bottom cage member 606 is located proximate to the bottom surface 732 of the cable connector 724. As a non-limiting example, the first end 610 may be configured to receive a cable connector 724 corresponding to a QSFP cable connector, such that the QSFP is secured to the cage receptacle assembly 600 by engaging at least a part of the inner surface 618 of the cage body 601 via the first end 610.

The cage body 601 may further define a second end 608 opposite the first end 610, where the second end 608 is configured to be received by a module for enabling signals to pass between the cable connector 724 and a module. The cage 600 may be configured to engage, or be secured to, a module (e.g., switch module 412). The cage receptacle assembly 600 may be configured such that the second end 608 defines at least one extension capable of being received by a datacenter switch module 412 (e.g., male to female connection). As discussed above, the opening 720 defined by the cage body 601 of the cage 600 may be such that a cable connector 724 may extend through the cage body 601 of the cage receptacle assembly 600. Specifically, the cable connector 724 may be configured (e.g., sized and shaped) such that upon engagement of the second end 608 of the cage receptacle assembly 600 with the module, the cable connector 724 may also engage the switch module 412 such that signals may be transmitted between the cable 724 and switch module 412.

By way of a more particular example, a connector 724 may be received by the cage 600 such that at least a portion of the connector 724 is supported and/or surrounded by the cage body 601 of the cage 600. Illustratively, connector 724 (e.g., the end of a cable configured to engage a module and allow electrical communication therethrough) may be positioned such that when the cage 600 engages the module 412, the connector plug 724 engages a corresponding port of the system to allow signals (e.g., electrical signals, optical signals, or the like) to travel between the connector and the module.

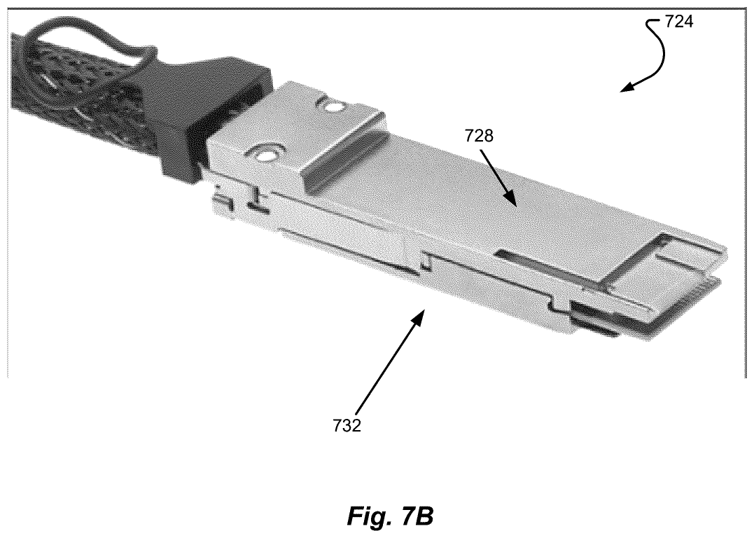

Turning now to FIGS. 8-13, a system 800 according to at least some embodiments of the present disclosure comprises a printed circuit board (PCB) 804, a heat exchange surface 808, and one or more cages 600. The PCB 804 may be, for example, any printed circuit board or alternative structure utilized in a datacenter such as the datacenter 202 for supporting and/or electrically connecting components of a communication network 204 and/or of a network device 206. The PCB 804 may additionally or alternatively be any material or structure to which cage assembly bodies such as the cages 600 may be mounted. In some embodiments, the PCB 804 and the manifold 824 may be made of the same material (e.g. copper) to facilitate the heat transfer.

The system 800 may be incorporated, for example, into a liquid-cooled switch, including any switch or switch system described or referenced herein or into a liquid-cooled server. The medium of transmission is any type of networking cable, e.g., direct attach copper (DAC), active copper cable (ACC), active optical cables (AOCs), cable assembly with OSFP connectors or the like) or interconnect utilized by datacenter racks and associated switch modules (e.g., a Small Form Pluggable (SFP), quad small form-factor pluggable (QSFP), or the like). It may also be a passive copper cable (PCC), an active optical cable and an active optical module for transmitting optical signals. In other alternative cases, the cable may also include an Ethernet cable, active optical cables (AOCs) or cable assembly with OSFP connectors. The semiconductor device may be a pluggable network interface device may comprise the male end portion of a direct attach cable assembly (DAC). The network connectors may each be configured to connect to a networking device of any type (e.g., QSFP, Direct Attach Copper, active optical cables (AOC), etc.), and may thus be dimensioned (e.g., sized and shaped) to mate with or otherwise connect to any corresponding networking device. The cable connector may be of any type (e.g., an AOC connector, Ethernet connector, Direct Attach Copper connector, Active Optical Module, or the like). A PCB is used to electrically connect electronic components using conductive pathways, or traces, etched from metal sheets. In many electronic systems, one or more very large-scale integrated circuit (“VLSI”) components is coupled to a host system printed circuit board (“PCB”). Such VLSI components may include, for example, central processing unit (“CPU) devices and graphics processing unit (“GPU”) devices. The PCB may hold at least one processing circuitry. The processing circuitry may comprise hardware, such as an application specific integrated circuit (ASIC). The processing circuitry may comprise an ASIC and/or may be capable of performing as a central processing unit (CPU), a graphics processing unit (GPU), a network interface controller (NIC), a data processing unit (DPU), or any other computing device in which with data is received and/or transmitted. Other non-limiting examples of the processing circuitry include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. It should be appreciated that any appropriate type of electrical or optical component or collection of electrical or optical components may be suitable for inclusion in the processing circuitry. Numerous example embodiments will be described below in which a semiconductor package is mounted within a through hole of a PCB. Although PCBs having certain types and form factors appear in the drawings and the discussion, it should be noted that the illustrated and described types and form factors are provided by way of example only. Persons having skill in the art and having reference to this disclosure will readily appreciate that the same or similar apparatus and techniques may also be employed with PCBs having other types and form factors. For example, in some embodiments, the PCB to which the semiconductor package is mounted may comprise an add-in card, such as a PCIe card, that is configured to be coupled to a system board or motherboard of a host system. In other embodiments, the PCB to which the semiconductor package is mounted may be the system board or motherboard of the host system itself. Moreover, the system board or the motherboard may be associated with any type of host system. For example, the PCB may comprise the system board in a multi-node rack-mounted server in a data center, or it may comprise the motherboard of a workstation, desktop, laptop, or mobile device. Other embodiments are also possible. Indeed, it should be appreciated that embodiments of the present disclosure are not limited to the cooling of PCBs in a particular environment, such as a data center, workstation, desktop, laptop, mobile device, or the like. Such environments are simply described as non-limiting examples of devices in which a cooling solution can be beneficial.

The cages 600 may be connected or otherwise grouped together in cage sets 860 (each comprising, for example, four cages 600, or five cages 600, or six cages 600, or seven cages 600, or eight cages 600). The cage sets 860 (or, in some embodiments, the individual cages 600) may be mounted to just one side of the PCB 804 and/or the heat exchange surface 808, and/or to both sides of the PCB 804 (e.g. upper and lower PCB surfaces defining a first and second plane, respectively) and/or the heat exchange surface 808. In some embodiments, the cage sets 860 or individual cages 600 may be mounted in a belly-to-belly configuration, meaning that a bottom side of the cages 600 mounted to or adjacent an upper surface of the PCB 804 and/or the heat exchange surface 808 faces a bottom side of the cages 600 mounted to or adjacent a lower surface of the PCB 804 and/or the heat exchange surface 808, and vice versa.

The PCB 804 comprises a cutout 806 in which the heat exchange surface 808 is implanted or mounted. The heat exchange surface 808 may alternatively be referred to herein as a cooling coin 808 and/or as a cooling plate 808. The heat exchange surface 808 is secured to the PCB 804 via a press fit (also known as a friction fit or an interference fit) using heat and/or pressure. Protrusions 866 positioned around an outer perimeter of the heat exchange surface 808 increase the friction between the heat exchange surface 808 and the inner perimeter of the cutout 806 of the PCB 804, so as to increase the friction between the heat exchange surface 808 and the PCB 804 and thus increase the strength of the press fit. In other embodiments of the present disclosure, the heat exchange surface 808 is mounted to the PCB 804 using one or more mechanical fasteners, such as screws, staples nails, clips, pins, and/or clamps. In still other embodiments, the PCB 804 may be mounted to the PCB 804 using glue, tape, and/or any other adhesive material or substance. In further embodiments, the heat exchange surface 808 and the PCB 804 may be configured to enable one to snap onto or click into the other without the use of any separate fasteners or other components.

Once the heat exchange surface 808 is mounted within the cutout 806 of the PCB 804, a top surface of the heat exchange surface 808 (comprising a top surface 870 of the cover plate 812 and a top surface 872 of the base 810), as well as an upper surface 874 of the PCB 804, may be milled, ground, or otherwise machined to ensure that the upper surfaces 870, 872, and 874 are coplanar such that the upper PCB surface 874 is substantially level with the top surface 870 of the cold plate. A similar milling, grinding, or other machining operation may be carried out to ensure that a bottom surface of the heat exchange surface 808 and a lower surface of the PCB 804 are coplanar such that the lower PCB surface 804 is substantially level with the bottom surface 808 of the cold plate. Alternatively, careful mounting of the heat exchange surface 808 within the PCB cutout 806 may be sufficient to ensure that the bottom surfaces of the heat exchange surface 808 and the PCB 804 are coplanar, such that only the upper surfaces 870, 872, and 874 require milling or other machining to ensure those surfaces are coplanar.

The system 800 comprises two manifolds 824 secured to the heat exchange surface 808 (although, in other embodiments of the present disclosure, three or more manifolds 824 may be utilized with the system 800 to channel fluid to and from the heat exchange surface 808). A pipe 832 extends from each manifold 824 and comprises a fitting 836 that can be detachably connected to a fluid source, such as the fluid source 504 described in connection with FIG. 5. The fittings 836 may be used to removably connect the pipes 832 (and thus the manifolds 824) directly to one or more tanks, reservoirs, lakes, ponds, rivers, streams, oceans, and/or other fluid containers or receptacles from which heat transfer fluid (including any heat transfer fluid described herein or any other heat transfer fluid) may be transported into the heat exchange surface 808 and/or into which heat transfer fluid exiting the heat exchange surface 808 may be deposited.

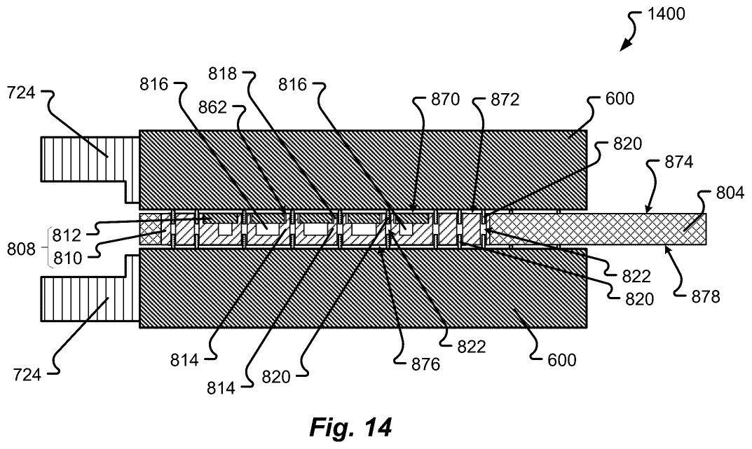

Still with reference to FIGS. 8-13, the heat exchange surface 808 comprises a base 810 and a cover plate 812. The base 810 defines an outer perimeter of the heat exchange surface 808, and protrusions 866 extend from the outer perimeter of the base 810. The base 810 also defines (at least partially) a fluid reservoir or conduit 840 comprising one or more channels 816, an inlet channel 844, and an outlet channel 852. The fluid reservoir or conduit 840 is positioned between a first plane defined by the upper surface 872 of the base 810 and a second plane defined by the lower surface 876 (visible in FIG. 14) of the base 810. Some or all of the channels 816 may be defined by one or more channel walls 814. The cover plate 812 encloses the fluid reservoir or conduit 840 as well as the channels 816, and consequently defines at least one surface of the fluid reservoir or conduit 840, as well as of the channels 816.

Both the PCB 804 and the heat exchange surface 808 comprise, in at least some embodiments of the present disclosure, a plurality of fastener holes 822 configured to receive fasteners 820 that secure the cages 600 and/or the cage sets 860 to the PCB 804 and/or the heat exchange surface 808. The fasteners may engage the fastener holes 822 via a press fit (e.g., a friction fit or an interference fit), or may screw into, snap into, and/or clip into the fastener holes 822, or may engage the cooling coin in any other manner sufficient to secure the cages 600 to the heat exchange surface 808. In some embodiments, some fasteners 820 engage the corresponding fastener holes 822 in a first manner (e.g., via a press fit), while other fasteners 820 engage the corresponding fastener holes 822 in a second manner (e.g., the other fasteners 820 may screw into the corresponding fastener holes 822). Heat and/or pressure may be applied to one or more of the cages 600, cage sets 860, PCB 804, and/or the heat exchange surface 808 to facilitate the securing of the cages 600 and/or cage sets 860 to the PCB 804 and/or the heat exchange surface 808. In some embodiments, the fasteners 820 may be fashioned from a heat-conductive material such as metal and may facilitate the transfer of heat from the cages 600 to the heat exchange surface 808 and, ultimately, to a heat transfer fluid flowing through the reservoir or conduit 840. The base 810 also comprises, according to some embodiments of the present disclosure, a plurality of fastener holes 822 configured to receive fasteners 820 that secure the manifolds 824 to the heat exchange surface 808.

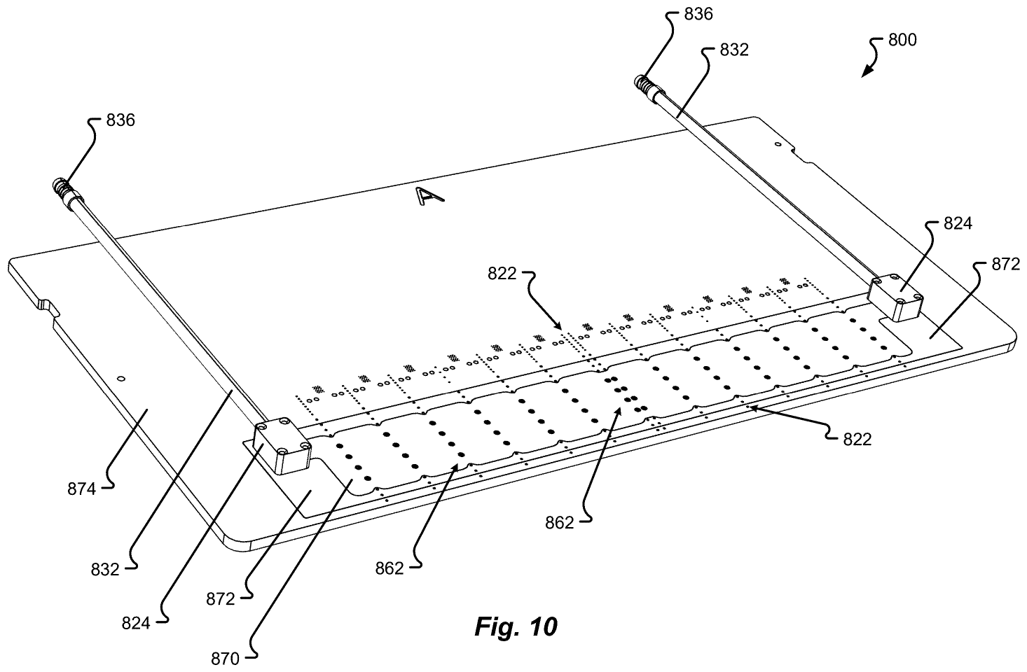

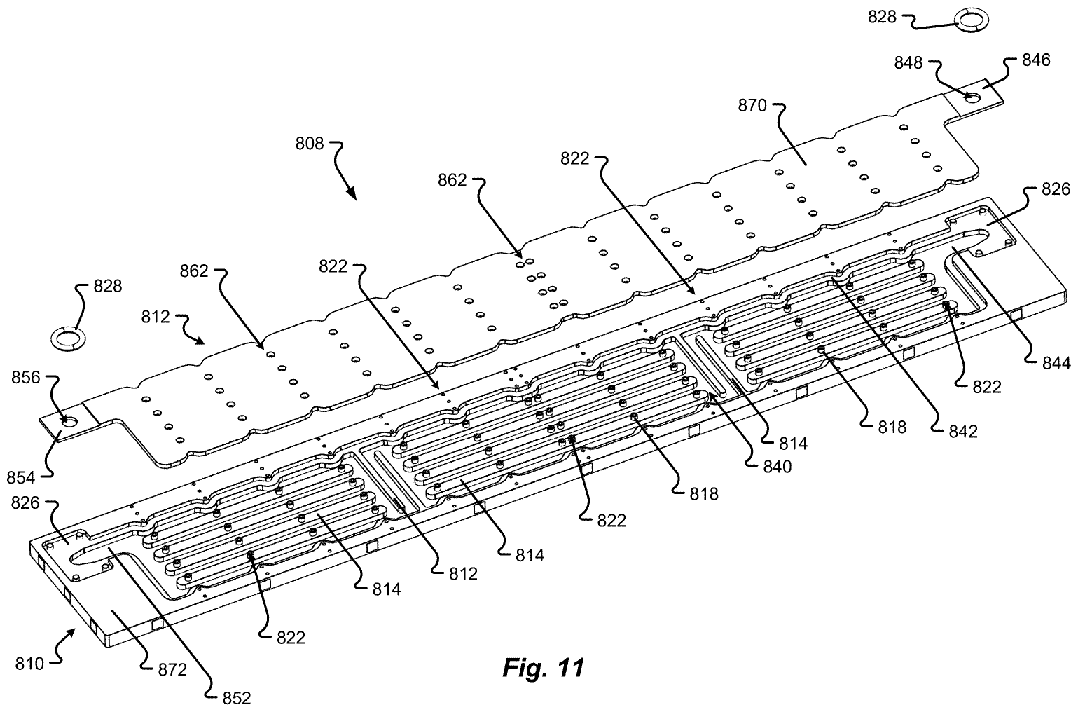

As shown in FIGS. 11-12 specifically, the reservoir or conduit 840 comprises multiple sections, each section comprising a plurality of parallel channels 816 and separated from one or more adjacent sections by one or more channel walls 814 that run perpendicular to the sections'parallel channels 816. In other embodiments of the present disclosure, the reservoir or conduit 840 comprises a single section comprising a single channel, or a single section comprising a plurality of parallel channels. Also in some embodiments, the conduit 840 comprises one or more curvilinear channels.

The conduit 840 also comprises an inlet channel 844 and an outlet channel 852. The inlet channel 844 extends from a main portion of the reservoir or conduit 840 to immediately underneath or adjacent an inlet port 848 (which may also be referred to as an intake port) in the cover plate 812, so as to provide a channel for heat transfer fluid to enter the reservoir or conduit 840 through the inlet port 848. The outlet channel 852 extends from a main portion of the conduit 840 to immediately underneath or adjacent an outlet port 856 (which may also be referred to as a discharge port) in the cover plate 812, so as to provide a channel for heat transfer fluid to leave the reservoir or conduit 840 through the outlet port 856.

The base 810 comprises a cover plate seat 842 that extends around some or all of a perimeter of the reservoir or conduit 840, and defines a surface that supports the cover plate 812 when it is mounted on the base 810. The tops of the channel walls 814 support the cover plate 812 when it is mounted on the base 810. The base 810 further comprises one or more manifold seats 826 configured to receive and support the manifolds 824. The cover plate seat 842 and the manifold seats 826 comprise a single contiguous surface, although in some embodiments of the present disclosure they may comprise separate surfaces. The cover plate seat 842 and the manifold seats 826 are separated from an upper surface 872 of the base 810 by a distance that is the same as, or substantially the same as, a thickness of the cover plate 812, so that when the cover plate 812 is seated on the cover plate seat 842 and/or the manifold seats 826, the upper surface 870 of the cover plate 812 is substantially coplanar with the upper surface 872 of the base 810.

The cover plate 812 may be mounted on the base 810 via a press fit (e.g., a friction fit or interference fit), or using one or more fasteners such as the fasteners 820, or using an adhesive material or substance, or using any other mounting method that allows the cover plate to be dismounted from the base 810 if and when desired. Where the cover plate 812 is mounted on the base 810 via a press fit, heat and/or pressure may be applied to one or both components to ensure a tight press fit. Where the cover plate 812 is mounted to the base 810 using fasteners 820, the fasteners may be dedicated fasteners used only to secure the cover plate 812 to the base 810. Alternatively, a single fastener 820 may be used to secure both the cage 600 and the cover plate 812 to the base 810. In yet other embodiments, the manifolds 824 may be configured to secure the cover plate 812 to the base 810 when the manifolds 824 are mounted to the base 810, whether using fasteners 820 or otherwise. In still other embodiments of the present disclosure, the cover plate 812 is permanently mounted to the base 810, whether by welding or otherwise.

In some embodiments of the present disclosure, one or more gaskets, one or more seals, a sealant, and/or one or more layers of polytetrafluoroethylene may be placed around the cover plate seat 842 to improve a fluid-tight seal between the cover plate 812 and the base 810.

The base 810 comprises a plurality of posts 818 extending upward from the top of the channel walls 814, such that an upper surface of the plurality of posts 818 is substantially coplanar with the upper surface 872 of the base 810. Each of the posts 818 surrounds a fastener hole 822, although in other embodiments of the present disclosure one or more posts 818 may not surround a fastener hole 822. The cover plate 812 comprises a plurality of post holes 862 configured to receive the posts 818, thus facilitating alignment of the cover plate 812 with the base 810 when the cover plate 812 is mounted to the base 810. The use of posts 818 surrounding the fastener holes 822 reduces the number of potential points of leakage of heat transfer fluid from the reservoir or conduit 840.

The cover plate 812 also comprises an inlet channel cover 846 positioned at a first end of the cover plate 812 and an outlet channel cover 854 positioned at a second end of the cover plate 812 opposite the first end. An inlet or intake port 848 extends through the inlet channel cover 846, and an outlet or discharge port 856 extends through the outlet channel cover 846. Heat transfer fluid enters the fluid reservoir or conduit 840 via the inlet port 848, and is channeled to the inlet port 848 from a fluid source (such as the fluid source 504) via a pipe 832 and a manifold 824. The manifold 824 comprises a gasket seat 830 configured to receive a gasket 828. When the manifold 824 is mounted to the base 810 over the inlet channel cover 846 or the outlet channel cover 854 of the cover plate 812, the gasket 828 is compressed against the cover plate 812, creating a fluid-tight seal between the manifold 824 and the cover plate 812 and ensuring that heat transfer fluid passing through the manifold 824 and the inlet port 848 or the outlet port 856 does not leak from its intended flow path. The pipe 832 and manifold 824 define a transfer conduit 834 for transporting heat transfer fluid to or from the heat exchange surface 808, and more specifically to or from the reservoir or conduit 840.

The base 810 and the cover plate 812 of the heat exchange surface 808 are made of metal, although in other embodiments of the present disclosure they may be fashioned from or using any heat-conductive material (e.g., copper) or other material that allows heat transfer from the cages 600 mounted adjacent the heat exchange surface 808 to the heat transfer fluid in the reservoir or conduit 840 of the heat exchange surface 808.

The heat exchange surface 808 of FIGS. 8-13 is an elongated rectangle. In other embodiments of the present disclosure, however, the heat exchange surface 808 may be shaped differently. For example, the heat exchange surface 808 may be any geometric shape (e.g., square, rectangle, triangle, circle, oval). In some embodiments, the heat exchange surface 808 may have one or more bends, so as to define an L-shape or a U-shape. In each embodiment, the cutout 806 in the PCB 804 matches or substantially matches the shape of the heat exchange surface 808.

The inlet port 848 of the heat exchange surface 808 of FIGS. 8-13 is positioned at an opposite end of the cover plate 812 from the outlet port 856. In other embodiments of the present disclosure, however, the inlet port 848 and the outlet port 856 may be positioned at the same end of the cover plate 812, or in any other location of the cover plate 812. Also in some embodiments of the present disclosure, the cover plate 812 may comprise more than one inlet port 848, and/or more than one outlet port 856.

In some embodiments of the present disclosure, the cover plate 812 and/or the base 810 may comprise one or more fins extending into the channels 816 and/or other portions of the reservoir or conduit 840 to improve heat transfer from the heat exchange surface 808 to the heat transfer fluid passing through the reservoir or conduit 840 of the heat exchange surface 808.

Although the heat exchange surface 808 of FIGS. 8-13 comprises two pieces (a base 810 defining a fluid conduit and a cover plate 812 mountable to the base 810 and configured to enclose the fluid conduit and having a plurality of ports positioned to enable fluid flow into and out of the fluid conduit), in some embodiments of the present disclosure the heat exchange surface comprises a single piece manufactured using additive manufacturing and defining an intake such as the inlet port 848, a reservoir or conduit such as the reservoir or conduit 840 (which may, in turn, comprise one or more channels such as the channels 816, each of which may be linear or curvilinear), a discharge such as the outlet port 856, and/or one or more fastener holes such as the fastener holes 822.

FIG. 14 shows a cross-section of a system 1400 that is substantially similar to the system 800, and comprises many of the same elements: a PCB 804, a heat exchange surface 808 comprising a base 810 and a cover plate 812; and cages 600 mounted in a belly-to-belly configuration adjacent the heat exchange surface 808, using fasteners 820 extending into fastener holes 822. Connector plugs 724 extend from the cages 600 (although the cables to which the connector plugs 724 attach are not shown). The base 810 comprises channel walls 814 defining channels 816 for routing heat transfer fluid through the heat exchange surface 808, and posts 818 defining at least a portion of some fastener holes 822 and extending into post holes 862 in the cover plate 812. As can be seen in this cross-section view, the upper surface 870 of the cover plate 812, the upper surface 872 of the base 810, and the upper surface 874 of the PCB 804 are all co-planar. The lower surface 876 of the heat exchange surface 808 and the lower surface 878 of the PCB 804 (which lower surfaces 876 and 878 are parallel to the upper surfaces 870, 872, and 874) are also coplanar.

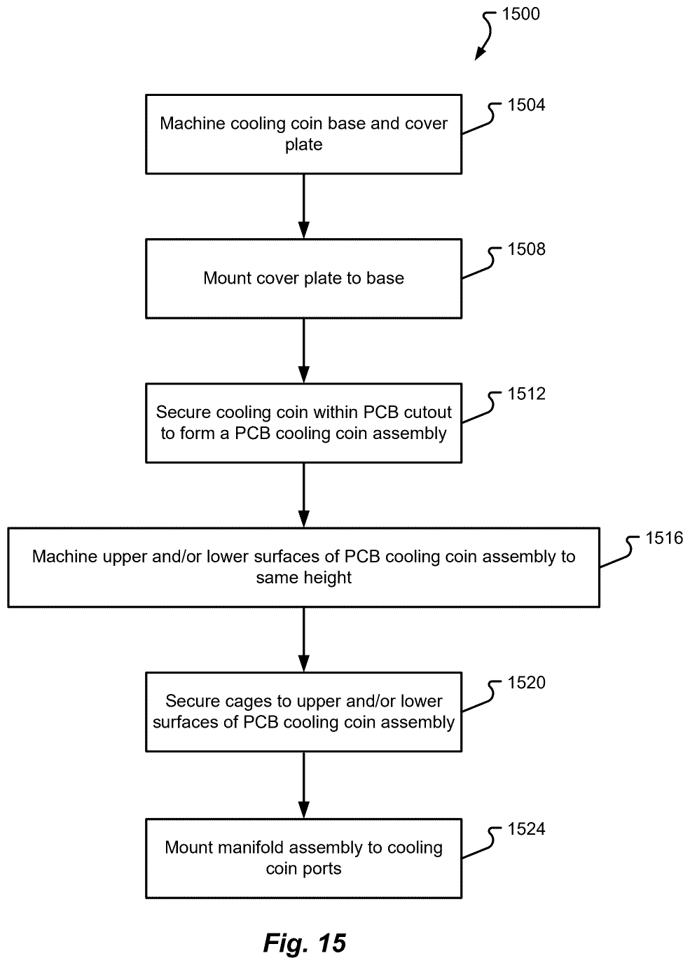

Turning now to FIG. 15, a method 1500 according to some embodiments of the present disclosure comprises machining a base and a cover plate of a cooling coin (step 1504). The step 1504 comprises machining, from a piece of metal, a base (such as the base 810) comprising a fluid reservoir (such as the fluid reservoir or conduit 840). The reservoir may comprise one or more channels (such as the channels 816) defined by one or more channel walls (such as the channel walls 814). The channels may be linear or curvilinear. In embodiments with a plurality of channels, all of the channels may be parallel to each other, or one or more channels may be perpendicular to one or more other channels. The reservoir may further comprise an inlet channel (such as the inlet channel 844) and an outlet channel (such as the outlet channel 852). The various channels of the reservoir may channel heat transfer fluid from an inlet or intake port of the reservoir to an outlet or discharge port of the reservoir (which inlet and outlet ports of the reservoir may be provided in the cover plate, such as the inlet or intake port 848 and the outlet or discharge port 856, or in the base).

The step 1504 also comprises machining a cover plate (such as the cover plate 812). The machining may comprise cutting an outer perimeter of the cover plate to match an inner perimeter of the base, so that the cover plate can be mounted within the base and achieve a fluid-tight connection.

The step 1504 may comprise, in some embodiments of the present disclosure, machining a cover plate seat (such as the cover plate seat 842) into the base; machining one or more posts (such as the posts 818) into the base; and machining one or more manifold seats (such as the manifold seats 826) into the base.

The step 1504 may comprise drilling a plurality of fastener holes (such as the fastener holes 822) into the cover plate and/or the base, as well as drilling a plurality of post holes (such as the post holes 862) into the cover plate. In some embodiments of the present disclosure, however, one or more fastener holes are drilled into the PCB cooling coin assembly during or after the step 1516, described below.

In some embodiments of the present disclosure, the step 1504 may comprise, instead of machining a base and a cover plate, manufacturing an integral cooling coin using additive manufacturing processes and procedures. In such embodiments, the cooling coin comprises a fluid pathway with one or more channels defining a flow path from a fluid pathway inlet to a fluid pathway outlet. The cooling coin in such embodiments also comprises one or more fastener holes (such as the fastener holes 822) for receiving fasteners used to mount one or more cages (such as the cages 600) to the cooling coin, which may be built into the cooling coin during the additive manufacturing process, or may be drilled into the cooling coin afterward.

The method 1500 also comprises mounting the cover plate to the base (step 1508). The mounting may comprise securing the cover plate to the base with a press fit (e.g., a friction fit or an interference fit), which may require applying heat and/or pressure to the one or both of the cover plate and the base. The mounting may comprise securing the cover plate to the base with one or more mechanical fasteners, and/or with an adhesive. The mounting may comprise welding the cover plate to the base. The result of the mounting is a cover plate with an upper surface substantially co-planar with an upper surface of the base (where the cover plate fits inside an inner perimeter of the base, and/or where one or more portions of the base form an upper surface of the cooling coin), or with an upper surface that completely defines the upper surface of the cooling coin (e.g., where the cover plate completely covers the base).

In some embodiments of the present disclosure, the step 1508 may comprise placing a gasket, a seal, or sealant between the cover plate and the base prior to mounting the cover plate to the base, so as to ensure a fluid-tight connection between the cover plate and the base.

The method 1500 also comprises securing the cooling coin within a cutout of a PCB board, so as to form a PCB cooling coin assembly (step 1512). The securing may comprise utilizing heat and/or pressure to secure the cooling coin within the PCB cutout using a press fit (e.g., a friction fit or an interference fit). The securing may alternatively comprise securing the cooling coin within the cutout using one or more mechanical fasteners; glue, tape, and/or some other adhesive; or any other process and/or device useful for securing a component such as the cooling coin to a component such as a PCB. Following the securing, the cooling coin may extend beyond one or both of the planes defined by the upper and lower surfaces of the PCB by 1 mm or less, or by 0.5 mm or less, or by 0.1 mm or less.

The method 1500 also comprises machining an upper surface and/or a lower surface of the PCB cooling coin assembly to the same height (step 1516). The machining may comprise milling, grinding, and/or any other machining process suitable for removing material from the cooling coin and/or the PCB so that an upper surface of the cooling coin is coplanar with an upper surface of the PCB, and/or so that a lower surface of the cooling coin is coplanar with a lower surface of the PCB. The machining may be done manually (e.g., using a milling machine) or using a CNC (computer numerical control) machine or similar device.

The method 1500 also comprises securing one or more cages to the upper and/or lower surfaces of the PCB cooling coin assembly (step 1520). The cages, which may be the same as or similar to the cages 600 described herein, may comprise one or more fasteners (such as the fasteners 820), which may be press fit into the fastener holes of the PCB cooling coin assembly. The cages 600 may also be screwed to the PCB cooling coin assembly using screws, nailed to the PCB cooling coin assembly using nails, stapled to the PCB cooling coin assembly using staples, clamped to the PCB cooling coin assembly using clamps, pinned to the PCB cooling coin assembly using pins, and/or otherwise connected to the PCB cooling coin assembly in any other suitable for securing the cages 600 adjacent the PCB cooling coin assembly.

The method 1500 also comprises mounting a manifold assembly to each of the cooling coin ports (step 1524). The manifold assembly comprises a manifold (such as the manifold 824), a pipe (such as the pipe 832), and a fitting (such as the fitting 836), although in some embodiments the manifold assembly may comprise more or fewer components. In some embodiments of the present disclosure, for example, the manifold assembly also comprises a gasket (such as the gasket 828), while in other embodiments the manifold assembly does not include, for example, a fitting.

The mounting may comprise using one or more fasteners (such as the fasteners 820) to secure the manifold assembly to the PCB cooling coin assembly, using any connection method described herein or any other connection method suitable for securing the manifold assembly to the PCB cooling coin assembly.

The present disclosure contemplates that the present disclosure may be created from any suitable material known in the art (e.g., carbon steel, aluminum, polymers, ceramics, and the like), particularly materials possessing high thermal conductivity. By way of example, cage receptacle assemblies as described herein may be created by an extrusion and/or machine process. In such an example, a single body of fixed cross-sectional area may be produced by an extrusion process. This single body may be created via pushing a base material (e.g., a polymer) through a dimensioned die such that the cage body 601 of the cage receptacle assembly is created. In some embodiments, the single body may be created as two separate elements (e.g., a top cage member and bottom cage member) where the two separate elements are further attached to form the single body. This extruded body may then be modified through a machine process whereby material is removed from the extruded body to create the finished cage receptacle assembly 600. The machining process may include any or all of micro machining, turning, milling, drilling, grinding, water jet cutting, EDM, EDM, AFM, USM, CNC, and the like, in any order or combination. Although described as an extrusion and machine process of a single piece of material, any portion or sub-portion of the cage receptacle assembly may be separately formed or attached without departing from the scope of this disclosure.

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components (e.g., components of printed circuit boards, transceivers, cables, etc.) may be used in conjunction with the cage receptacle assembly. Therefore, it is to be understood that the disclosures are not to be limited to the specific embodiments disclosed and that modifications and other embodiments are intended to be included within the scope of the appended claims.

It is to be appreciated that any feature described herein can be claimed in combination with any other feature(s) as described herein, regardless of whether the features come from the same described embodiment.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A system, comprising:
a Printed Circuit Board (PCB);
one or more cages mounted on a surface of the PCB; and
a heat exchange surface integrated into the PCB and configured to carry a heat transfer fluid that cools the one or more cages.

2. The system of claim 1, wherein the heat exchange surface comprises:
an intake port;
a discharge port; and
a conduit, the intake port in fluid communication with the discharge port via the conduit.

3. The system of claim 2, wherein the heat exchange surface further comprises:
a base; and
a cover plate secured to the base,
wherein each of the base and the cover plate define a surface of the conduit.

4. The system of claim 3, wherein the conduit comprises a plurality of channels machined into the base.

5. The system of claim 3, wherein the cover plate comprises:
a first end;
a second end opposite the first end;
the intake port proximate the first end; and
the discharge port proximate the second end.

6. The system of claim 2, further comprising:
a manifold secured to the heat exchange surface and in fluid communication with the intake port, the manifold detachably connectable to a heat transfer fluid source.

7. The system of claim 1, wherein the heat exchange surface is secured to the PCB via a press fit.

8. The system of claim 1, wherein the heat exchange surface is machined to have a final height that matches a height of the PCB.

9. The system of claim 1, wherein the PCB comprises an upper PCB surface and a lower PCB surface, the heat exchange surface comprises a top surface and a bottom surface, the upper PCB surface is substantially level with the top surface, and the lower PCB surface is substantially level with the bottom surface.

10. The system of claim 9, wherein the one or more cages comprises:
a first plurality of cages mounted to the upper PCB surface with a belly side of the first plurality of cages facing the upper PCB surface; and
a second plurality of cages mounted to the lower PCB surface with a belly side of the second plurality of cages facing the lower PCB surface.

11. The system of claim 1, wherein each of the one or more cages is configured to receive a connector plug.

12. The system of claim 10, wherein the connector plug is a Quad Small Form-factor Pluggable (QSFP) plug or an Octal Small Form-factor Pluggable (OSFP) plug.

13. A liquid-cooled switch, comprising the system of claim 1.

14. A liquid-cooled server, comprising the system of claim 1.

15. A liquid-cooled system comprising:
a Printed Circuit Board (PCB) comprising:
an upper surface defining a first plane; and
a lower surface defining a second plane;
one or more cages mounted on each of the upper surface and the lower surface of the PCB; and
a cooling coin embedded in the PCB, the cooling coin defining a pathway positioned in between the first plane and the second plane, the pathway configured to hold a heat transfer fluid.

16. The liquid-cooled system of claim 15, wherein the cooling coin comprises:
an intake port in fluid communication with the pathway; and
a discharge port in fluid communication with the pathway.

17. The liquid-cooled system of claim 15, wherein the pathway comprises a plurality of channels.

18. The liquid-cooled system of claim 16, wherein the cooling coin comprises a base and a cover plate.

19. A system, comprising:
a cooling plate, comprising:
a first piece defining a fluid conduit;
a second piece mountable to the first piece and configured to enclose the fluid conduit; and
a plurality of ports positioned to enable fluid flow into and out of the fluid conduit.

20. The system of claim 19, wherein at least one of the plurality of ports is positioned in the second piece.

21. The system of claim 19, wherein the fluid conduit comprises a plurality of fluid paths for channeling fluid from a first one of the plurality of ports to a second one of the plurality of ports.

22. The system of claim 19, wherein the cooling plate further comprises:
an inlet manifold mounted to the first piece and configured to channel fluid through a first one of the plurality of ports; and
an outlet manifold mounted to the first piece and positioned to receive fluid exiting the fluid conduit through a second one of the plurality of ports.

23. The system of claim 19, further comprising:
a first plurality of cages mounted adjacent the first piece; and
a second plurality of cages mounted adjacent the second piece,
wherein the first plurality of cages is in a belly-to-belly configuration relative to the second plurality of cages.
